(19) United States
(12) Patent Application Publication
(10) Pub. No.: US 2025/0318363 A1
(43) Pub. Date: Oct. 9, 2025

(54) DISPLAY DEVICE AND METHOD OF MANUFACTURING THE SAME

(71) Applicant: Samsung Display Co., LTD., Yongin-si (KR)

(72) Inventors: Kwang Soo LEE, Yongin-si (KR); Ki Wook KIM, Yongin-si (KR); So Jung YOON, Yongin-si (KR); So Young LEE, Yongin-si (KR)

(73) Assignee: Samsung Display Co., LTD., Yongin-si (KR)

(21) Appl. No.: 18/985,894

(22) Filed: Dec. 18, 2024

(30) Foreign Application Priority Data
Apr. 4, 2024 (KR) 10-2024-0046030

(51) Int. Cl. H10K 59/122; H10K 59/12; H10K 59/80

(52) U.S. Cl. CPC H10K 59/122; H10K 59/1201; H10K 59/8723

(57) ABSTRACT

A display device according to an embodiment includes a substrate including a display area including light emitting areas, pixels disposed on the substrate and including light emitting elements disposed in the light emitting areas, a pixel defining layer disposed on the substrate and surrounding the light emitting areas, a spacer disposed on a portion of the pixel defining layer, and a first pattern formed in at least one of the pixel defining layer and the spacer, the first pattern including a protrusion and grooves disposed at sides of the protrusion.

### CROSS-REFERENCE TO RELATED APPLICATION(S)

This application claims priority to and benefits of Korean Patent Application No. 10-2024-0046030 under 35 U.S.C. § 119 filed on Apr. 4, 2024, in the Korean Intellectual Property Office, the entire contents of which are incorporated herein by reference.

### BACKGROUND

### 1. Technical Field

The disclosure relates to a display device and a method of manufacturing the display device.

### 2. Description of the Related Art

As an information society develops, the demand for a display device for displaying an image is increasing in various forms. In response to this, various types of display devices, including light emitting display devices, are being developed. The light emitting display device may include a pixel including a light emitting element.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device capable of preventing pixel defects due to moisture permeation or leakage current, and a method of manufacturing the display device.

Aspects of the disclosure also provide an electronic device for providing an image, including the display device.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an aspect of the disclosure, there is provided a display device that includes a substrate including a display area including light emitting areas; pixels disposed on the substrate and including light emitting elements disposed in the light emitting areas; a pixel defining layer disposed on the substrate and surrounding the light emitting areas; a spacer disposed on a portion of the pixel defining layer; and a first pattern formed in at least one of the pixel defining layer and the spacer, the first pattern including a protrusion and grooves disposed at sides of the protrusion.

In an embodiment, the grooves may be entirely disposed around a circumference of the protrusion.

In an embodiment, the display device may further include a second pattern disposed on the protrusion.

In an embodiment, the second pattern may include a metal or an oxide.

In an embodiment, the second pattern may completely cover an upper surface of the protrusion.

In an embodiment, the protrusion may have a shape and size substantially corresponding to a shape and size of the second pattern.

In an embodiment, the spacer may be disposed between a first light emitting area and a second light emitting area that are adjacent to each other in a first direction among the light emitting areas, and the spacer may extend in a second direction intersecting the first direction.

In an embodiment, the first pattern may be formed in the pixel defining layer and disposed at sides of the spacer in the first direction.

In an embodiment, the first pattern may be disposed between the first light emitting area and the second light emitting area and may surround the spacer.

In an embodiment, each of the light emitting elements may include, a first electrode disposed on the substrate and disposed in a light emitting area of each of the pixels, a light emitting layer disposed on the first electrode, and a second electrode disposed on the light emitting layer and entirely disposed in the display area.

In an embodiment, the second electrode may be partially disconnected or may have a level difference on the first pattern.

In an embodiment, each of the light emitting elements may further include an intermediate layer disposed between the first electrode and the second electrode and overlapping the light emitting layer.

In an embodiment, the intermediate layer may be entirely disposed in the display area and may be partially disconnected or may have a level difference on the first pattern.

In an embodiment, a height difference between the protrusion and the groove may be substantially greater than or equal to a thickness of the intermediate layer.

In an embodiment, the display device may further include a filler and an upper substrate disposed on the light emitting elements.

In an embodiment, display device may further include a multi-layer encapsulation layer disposed on the light emitting elements.

According to an aspect of the disclosure, there is provided a method of manufacturing a display device, the method may include, preparing a substrate including light emitting areas and a non-light emitting area disposed between the light emitting areas; forming first electrodes in the light emitting areas on the substrate; forming a pixel defining layer and a spacer in the non-light emitting area on the substrate; forming a first pattern including a groove in at least one of the pixel defining layer and the spacer; and forming an organic layer including respective light emitting layers on the first electrodes and forming a second electrode on the organic layer, wherein the second electrode may be entirely formed in a display area including the light emitting areas and the non-light emitting area, and may be partially disconnected or has a level difference on the first pattern.

In an embodiment, the forming of the first pattern may include, forming a second pattern on a portion of at least one of the pixel defining layer and the spacer, and forming the groove in at least one of the pixel defining layer and the spacer by using the second pattern as a mask.

In an embodiment, the second pattern may be formed of a metal or an oxide.

In an embodiment, the organic layer further may include an intermediate layer overlapping the light emitting layers, and the intermediate layer may be entirely disposed in the display area and may be partially disconnected or has a level difference on the first pattern.

According to an aspect of the disclosure, there is provided an electronic device for providing an image, including a display device. The display device may include a substrate including a display area including light emitting areas; pixels disposed on the substrate and including light emitting elements disposed in the light emitting areas; a pixel defining layer disposed on the substrate and surrounding the light emitting areas; a spacer disposed on a portion of the pixel defining layer; and a first pattern formed in at least one of the pixel defining layer and the spacer, the first pattern including a protrusion and grooves disposed at sides of the protrusion.

In an embodiment, the grooves may be entirely disposed around a circumference of the protrusion.

In an embodiment, the spacer may be disposed between a first light emitting area and a second light emitting area that are adjacent to each other in a first direction among the light emitting areas, and the spacer may extend in a second direction intersecting the first direction.

According to the display device and the method of manufacturing the display device according to embodiments, it is possible to prevent damage or performance degradation of the light emitting element due to moisture permeation or leakage current by disposing the first pattern including the groove around the light emitting area. Accordingly, it is possible to prevent or reduce defects or degradation in luminance of the pixel, and increase the reliability of the pixel and the display device including the pixel.

However, effects according to the embodiments of the disclosure are not limited to those described above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic plan view illustrating a display panel of FIG. 1;

FIG. 3 is a schematic diagram of an equivalent circuit illustrating a pixel according to an embodiment;

FIG. 4 is a schematic plan view illustrating a display area according to an embodiment;

FIG. 5 is a schematic plan view illustrating a display area according to an embodiment;

FIG. 6 is a schematic cross-sectional view illustrating a display panel according to an embodiment;

FIG. 7 is a schematic plan view illustrating a display area according to an embodiment;

FIG. 8 is a schematic plan view illustrating a display area according to an embodiment;

FIG. 9 is a schematic cross-sectional view illustrating a display panel according to an embodiment;

FIG. 10 is a schematic plan view illustrating a display area according to an embodiment;

FIG. 11 is a schematic plan view illustrating a display area according to an embodiment;

FIG. 12 is a schematic plan view illustrating a display area according to an embodiment;

FIG. 13 is a schematic plan view illustrating a display area according to an embodiment;

FIG. 14 is a schematic cross-sectional view illustrating a display panel according to an embodiment;

FIG. 15 is a schematic cross-sectional view illustrating a display panel according to an embodiment;

FIG. 16 is a schematic cross-sectional view illustrating a display panel according to an embodiment;

FIG. 17 is a schematic cross-sectional view illustrating a display panel according to an embodiment;

FIG. 18 is a schematic cross-sectional view illustrating a display panel according to an embodiment;

FIG. 19 is a schematic plan view illustrating a display area according to an embodiment;

FIG. 20 is a schematic plan view illustrating a display area according to an embodiment;

FIG. 21 is a schematic cross-sectional view illustrating a display panel according to an embodiment;

FIG. 22 is a schematic cross-sectional view illustrating a display panel according to an embodiment; and

FIGS. 23 to 27 are schematic cross-sectional views illustrating a method of manufacturing a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Features of each of various embodiments may be partially or entirely combined with each other and may technically variously interwork with each other, and respective embodiments may be implemented independently of each other or may be implemented together in association with each other.

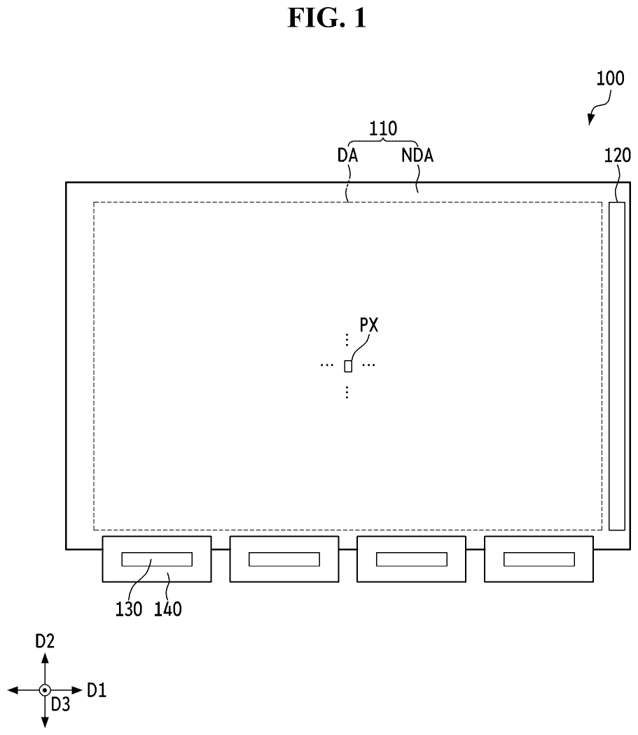

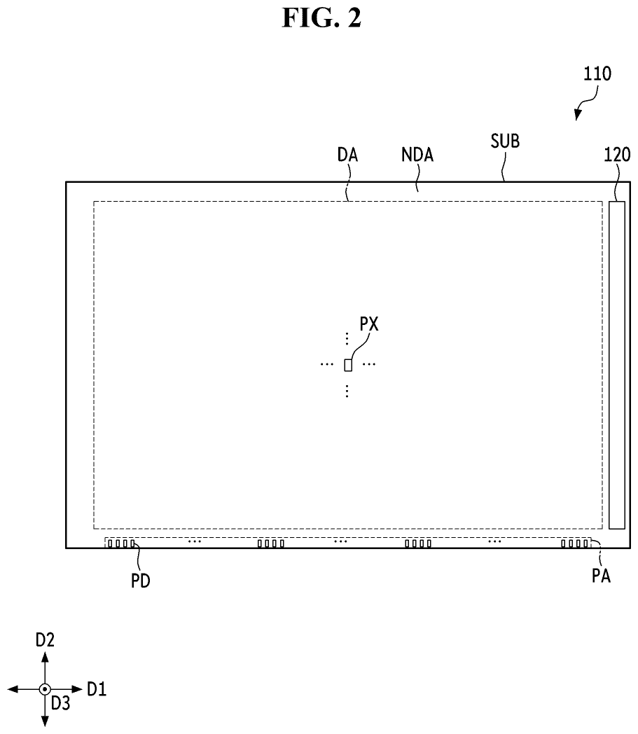

FIG. 1 is a schematic plan view illustrating a display device according to an embodiment. FIG. 2 is a schematic plan view illustrating a display panel of FIG. 1.

Referring to FIGS. 1 and 2, a display device 100 is a device that displays a moving image or a still image, and may be used as a display screen of each of various products such as a television, a laptop computer, a monitor, a billboard, and an Internet of Things (IoT) device as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, and an ultra mobile PC (UMPC). These are presented as examples of electronic devices including the display device 100 and capable of providing an image, and the display device 100 may also be included or employed in other electronic devices.

In an embodiment, the display device 100 may be a light emitting display device such as an organic light emitting display device using an organic light emitting diode, a quantum dot light emitting display device including a quantum dot light emitting layer, an inorganic light emitting display device including an inorganic semiconductor, and a micro or nano light emitting display device including a micro or nano light emitting diode (LED), but is not limited thereto. For example, the display device 100 may be a type of display device other than the light emitting display device. Hereinafter, embodiments in which the display device 100 is a light emitting display device (for example, an organic light emitting display device) are disclosed.

The display device 100 may include a display panel 110 including pixels PX, and a first driver 120 and a second driver 130 that supply driving signals to the pixels PX. The display device 100 may further include additional components. For example, the display device 100 may further include a power supply unit for supplying power voltages to the pixels PX, the first driver 120, and the second driver 130, a timing control unit for controlling operations of the first driver 120 and the second driver 130.

The display panel 110 may include a display area DA and a non-display area NDA. The display area DA may be an area that may include the pixels PX and displays an image. For example, the display area DA may include pixel areas in which each pixel PX is disposed. The non-display area NDA is the remaining area excluding the display area DA, and an image may not be displayed in the non-display area NDA. In an embodiment, the non-display area NDA may be positioned around the display area DA and surround the display area DA.

In FIGS. 1 and 2, a first direction D1, a second direction D2, and a third direction D3 are defined. In an embodiment, the first direction D1 may be a horizontal direction of the display panel 110, and the second direction D2 may be a vertical direction of the display panel 110. The third direction D3 may be a thickness direction of the display panel 110.

In an embodiment, the display panel 110 may have a rectangular shape in plan view. FIGS. 1 and 2 illustrate the display panel 110 with a horizontal length longer than a vertical length, but the shape of the display panel 110 is not limited thereto. For example, the display panel 110 may have a shape in which the vertical length is longer than the horizontal length, or may have a square shape, etc. The display panel 110 may include angled corners or rounded corners.

The planar shape of the display panel 110 is not limited to the quadrangular shape, and may also be other shapes. For example, the display panel 110 may also have another polygonal shape, a circular shape, an elliptical shape, or other planar shapes.

The display panel 110 may be provided as a rigid panel so as not to be substantially deformed, or may be provided as a flexible panel that is deformed into a shape such as being folded, bent, or rolled at least in one portion. The display panel 110 may be provided to the display device 100 in an unbent state or may be provided to the display device 100 in a bent state in some sections.

The display panel 110 may include a substrate SUB and pixels PX disposed on the substrate SUB. The pixels PX may be disposed in the display area DA on the substrate SUB.

The substrate SUB is a base member for manufacturing or providing the display panel 110 and may form a base surface of the display panel 110. The substrate SUB may include a display area DA and a non-display area NDA around the display area DA.

The display area DA may have various shapes depending on embodiments. For example, the display area DA may have a quadrangular shape, a non-quadrangular polygonal shape, a circular shape, an elliptical shape, or other shapes. In an embodiment, the display area DA may have a shape that matches the shape of the display panel 110.

The pixels PX may be provided and/or arranged (or disposed) in the display area DA. For example, the display area DA may include pixel areas in which each pixel PX is disposed.

In an embodiment, the display device 100 may be a light emitting display device, and each pixel PX may include a light emitting element positioned in each light emitting area and a pixel circuit connected to the light emitting element. In describing the embodiments, “connection” may include electrical connection and/or physical connection. Each pixel circuit may include transistors (for example, transistors, including a driving transistor that generates a driving current corresponding to a data signal, and at least one switching transistor), and at least one capacitor (for example, a capacitor including a storage capacitor).

The non-display area NDA may include a pad area PA in which pads PD are disposed. In an embodiment, the non-display area NDA may further include a driving circuit area positioned on at least one side or a side of the display area DA. At least one driver, pads PD, and/or lines may be disposed in the non-display area NDA.

At least one driver for driving the pixels PX, or a portion of the driver may be disposed in the driving circuit area. As an example, circuit elements constituting the first driver 120 (for example, driver transistors and driver capacitors constituting stage circuits of the first driver 120) may be disposed in the driving circuit area on the substrate SUB. In an embodiment, the circuit elements of the first driver 120 may be formed in the display panel 110 together with the pixels PX. In an embodiment, the driver transistors provided in the first driver 120 may be transistors of substantially the same or similar type and/or structure as the transistors provided in the pixels PX, and may be formed simultaneously with the transistors of the pixels PX.

The pads PD may be disposed in the pad area PA. At least one circuit board 140 may be disposed and/or bonded onto the pad area PA. In an embodiment, circuit boards 140 connected to different pads PD may be disposed on the pad area PA. The pads PD may include signal pads and power pads for transmitting driving signals and power voltages for driving the pixels PX and/or the first driver 120 to the inside of the display panel 110.

The first driver 120 and the second driver 130 may generate driving signals for controlling an operation timing and luminance of the pixels PX, and supply the driving signals to the pixels PX. For example, the first driver 120 may be a gate driver including a scan driver, and may be connected to the pixels PX through the respective gate lines. The first driver 120 may supply respective gate signals (for example, control signals that control driving timing of the pixels PX, including scan signals and/or emission control signal) to the pixels PX. The second driver 130 may be a data driver including source driver circuits and may be connected to the pixels PX through the respective data lines. The second driver 130 may supply respective data signals to the pixels PX.

In an embodiment, at least one of the first driver 120 and the second driver 130, or a portion of the at least one driver, may be embedded in the display panel 110. For example, the first driver 120 or a portion of the first driver 120 may be disposed on the substrate SUB of the display panel 110 and may be disposed and/or formed in the non-display area NDA.

It is illustrated in FIGS. 1 and 2 that the first driver 120 is formed on one side or a side of the display area DA (for example, the non-display area NDA on the right side of the display area DA), but the embodiments are not limited thereto. For example, the first driver 120 may be positioned only on the other side of the display area DA (for example, the non-display area NDA on the left side of the display area DA), or may be positioned at sides (e.g., opposite sides) of the display area DA (for example, non-display areas NDA on the left and right sides of the display area DA). By way of example, a portion of the first driver 120 may be positioned in the non-display area NDA, and another portion of the first driver 120 may be positioned in the non-light emitting area (for example, an area between the light emitting areas of the pixels PX) inside the display area DA.

In an embodiment, the other of the first driver 120 and the second driver 130, or a portion of the other driver, may be disposed or formed outside the display panel 110 and may be electrically connected to the display panel 110. For example, the second driver 130 may be implemented with integrated circuit chips and may be disposed on the circuit boards 140 electrically connected to the pixels PX of the display panel 110. The second driver 130 may be implemented with at least one integrated circuit chip and may be mounted on the non-display area NDA of the display panel 110.

The circuit board 140 may be connected to the display panel 110 through pads PD. In an embodiment, the circuit board 140 may be a flexible film such as a flexible printed circuit board (FPCB), a printed circuit board (PCB), or a chip on film (COF), but is not limited thereto. In an embodiment, the circuit board 140 may be connected to the timing control unit and/or the power supply unit through another circuit board or a connector.

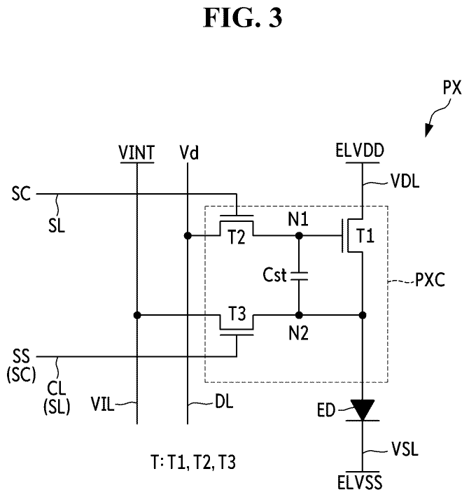

FIG. 3 is a schematic diagram of an equivalent circuit illustrating a pixel according to an embodiment. For example, FIG. 3 is a schematic diagram of an equivalent circuit illustrating a pixel PX of a light emitting display device including a light emitting element ED. The type and/or structure of the pixel PX included in the display device 100 may be variously changed depending on the embodiments.

Referring to FIG. 3, the pixel PX may include a light emitting element ED and a pixel circuit PXC connected to the light emitting element ED. The light emitting element ED is a light source of the pixel PX and may be, for example, an organic light emitting diode, but is not limited thereto. The pixel circuit PXC may control light emission of the light emitting element ED.

The pixel circuit PXC may include transistors T and a capacitor Cst. For example, the pixel circuit PXC may include a first transistor T1, a second transistor T2, a third transistor T3, and a capacitor Cst. FIG. 3 illustrates an embodiment in which all transistors T are N-type transistors, but the type of transistors T is not limited thereto. For example, at least one transistor T may also be formed as a P-type transistor.

The pixel circuit PXC may supply a driving current to the light emitting element ED in response to the driving signals supplied from the first driver 120 and the second driver 130. For example, the pixel circuit PXC may supply the driving current to the light emitting element ED in response to a scan signal SC and a control signal SS supplied from the first driver 120 through a scan line SL and a control line CL, and a data signal Vd supplied from the second driver 130 through a data line DL.

FIG. 3 illustrates an embodiment in which the scan line SL and the control line CL are separated from each other, but the embodiments are not limited thereto. For example, the control line CL may be a portion of the scan line SL and branch from the scan line SL, and the control signal SS may be the scan signal SC.

The first transistor T1 may be a driving transistor of the pixel PX in which a size of a drain-source current (for example, the driving current) is determined depending on a gate-source voltage. The second and third transistors T2 and T3 may be switching transistors that are turned on or off depending on the respective gate-source voltages. Depending on the type (for example, P-type or N-type transistor) and/or operating conditions of each of the transistors T, a first electrode of each of the transistors T may be a drain electrode (or a drain region) or a source electrode (or a source region), and a second electrode thereof may be an electrode different from the first electrode. For example, in case that the first electrode is a drain electrode, the second electrode may be a source electrode.

The pixel PX may be connected to a scan line SL that transmits a scan signal SC, a control line CL that transmits a control signal SS (for example, a sensing control signal or an initialization control signal), and a data line DL that transmits a data signal Vd. The pixel PX may be connected to a first power line VDL that transmits a first driving voltage ELVDD (also referred to as “first pixel voltage”), and a second power line VSL that transmits a second driving voltage ELVSS (also referred to as “second pixel voltage”). A voltage level of the second driving voltage ELVSS may be lower than a voltage level of the first driving voltage ELVDD. In an embodiment, the pixel PX may be further connected to an initialization power line VIL that transmits a third driving voltage VINT (for example, an initialization voltage).

In an embodiment, the transistors T may be positioned in each pixel area and may be oxide transistors including an oxide semiconductor (also referred to as “oxide semiconductor transistors”). For example, an active layer of each of the first, second, and third transistors T1, T2, and T3 may include an oxide semiconductor. However, the embodiments are not limited thereto. For example, at least one transistor T may also be formed of other semiconductor materials (for example, amorphous silicon or polysilicon) other than the oxide semiconductor.

In an embodiment, a light blocking layer or a light blocking electrode (for example, a bottom electrode or a back-gate electrode) may be disposed below the active layer of at least one of the first, second, and third transistors T1, T2, and T3. As an example, a bottom electrode that blocks external light may be disposed below the active layer of the first transistor T1. Accordingly, operating characteristics of the first transistor T1 may be stabilized.

The first transistor T1 may include a gate electrode connected to a first node N1, a first electrode (for example, a drain electrode) connected to the first power line VDL, and a second electrode (for example, a source electrode) connected to a second node N2. The second node N2 may be a node where the pixel circuit PXC and the light emitting element ED are connected. The first transistor T1 may control the driving current of the pixel PX in response to the data signal Vd transmitted to the first node N1.

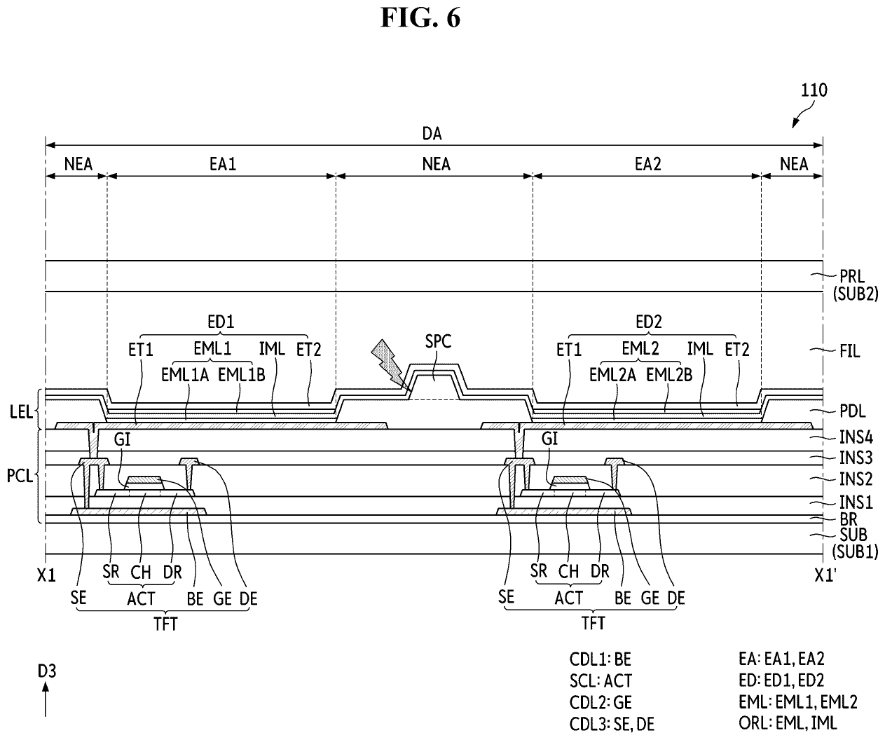

In an embodiment, the first transistor T1 may further include a bottom electrode (for example, a bottom electrode BE in FIG. 6) connected to the second node N2. In case that the bottom electrode of the first transistor T1 is connected to the second node N2 to form the first transistor T1 as a transistor with a double gate structure (for example, a double gate transistor with a source-sync structure), the operating characteristics of the first transistor T1 may be improved.

The second transistor T2 may include a gate electrode connected to the scan line SL, a first electrode connected to the data line DL, and a second electrode connected to the first node N1. The second transistor T2 may be turned on by a scan signal SC of a gate-on voltage applied to the scan line SL to connect the data line DL and the first node N1. Accordingly, the data signal Vd applied to the data line DL may be transmitted to the first node N1.

The third transistor T3 may include a gate electrode connected to the control line CL (or the scan line SL), a first electrode connected to the second node N2, and a second electrode connected to the initialization voltage line VIL. The third transistor T3 may be turned on by a control signal SS (or a scan signal SC) of a gate-on voltage applied to the control line CL (or the scan line SL) to connect the initialization voltage line VIL and the second node N2.

The capacitor Cst may be connected between the first node N1 and the second node N2. The capacitor Cst may store a voltage (for example, a difference between the gate voltage and the source voltage of the first transistor T1) corresponding to the data signal Vd (for example, the data voltage) transmitted to the first node N1.

The light emitting element ED may be connected between the pixel circuit PXC and the second power line VSL. For example, the light emitting element ED may include a first electrode (for example, an anode electrode) connected to the pixel circuit PXC through the second node N2, a second electrode (for example, a cathode electrode) facing the first electrode and connected to the second power line VSL, and a light emitting layer disposed between the first electrode and the second electrode. In an embodiment, the first electrode of the light emitting element ED may be a pixel electrode provided individually to each pixel PX, and the second electrode of the light emitting element ED may be a common electrode shared by the pixels PX. The light emitting element ED may emit light with a luminance corresponding to the driving current while the driving current is supplied from the pixel circuit PXC.

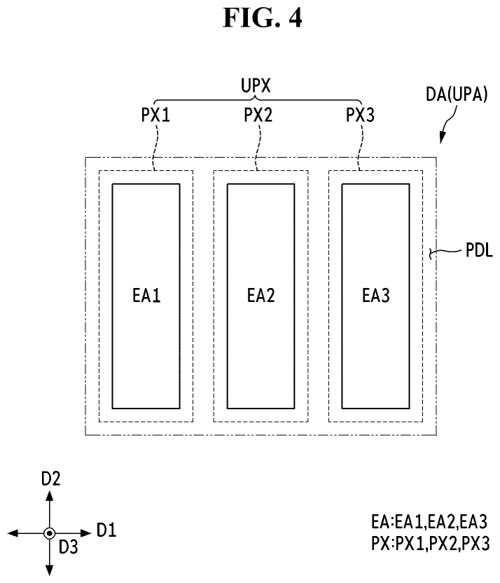

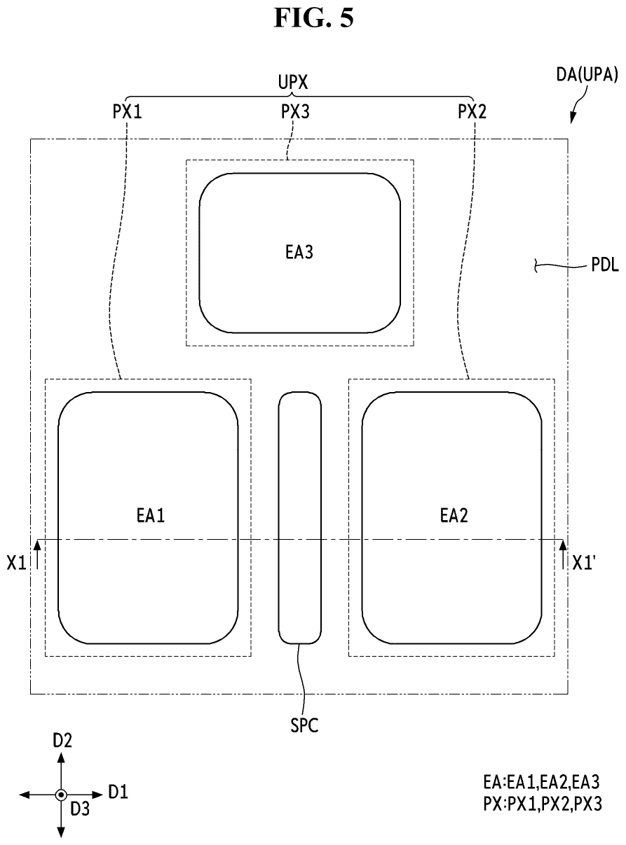

FIG. 4 is a schematic plan view illustrating a display area according to an embodiment. FIG. 5 is a schematic plan view illustrating a display area according to an embodiment.

For example, FIGS. 4 and 5 illustrate a portion of the display area DA corresponding to a unit pixel area UPA including the pixels PX disposed in the display area DA of FIGS. 1 and 2. FIGS. 4 and 5 illustrate different embodiments of an arrangement structure of the light emitting areas EA of the pixels PX arranged in the unit pixel area UPA.

Referring to FIGS. 4 and 5, the display area DA may include a unit pixel area UPA in which each unit pixel UPX is disposed. For example, the display area DA may include unit pixel areas UPA in which unit pixels UPX are disposed. FIGS. 4 and 5 illustrate the embodiments in which the unit pixel area UPA has a quadrangular shape, but the shape of the unit pixel area UPA may vary depending on the embodiments.

The unit pixel UPX may include at least two pixels PX that emit light of different colors. As an example, the unit pixel UPX may include a first pixel PX1, a second pixel PX2, and a third pixel PX3.

Each pixel PX may include at least one light emitting area EA. For example, the first pixel PX1, the second pixel PX2, and the third pixel PX3 may include a first light emitting area EA1, a second light emitting area EA2, and a third light emitting area EA3, respectively.

In an embodiment, the first light emitting area EA1, the second light emitting area EA2, and the third light emitting area EA3 may be sequentially arranged along the first direction D1 as illustrated in FIG. 4, or may be arranged in a delta shape or the like on a plane defined by the first direction D1 and the second direction D2. The first light emitting area EA1, the second light emitting area EA2, and the third light emitting area EA3 may also be arranged according to the unit pixel area UPA in a different arrangement form than the arrangement form according to the embodiments of FIGS. 4 and 5. The arrangement order of the first light emitting area EA1, the second light emitting area EA2, and the third light emitting area EA3 may vary depending on the embodiments.

The light emitting areas EA may be surrounded by a pixel defining layer PDL (also referred to as a “bank” or “organic film pattern”). The pixel defining layer PDL may be disposed in a non-light emitting area around the light emitting areas EA. For example, the pixel defining layer PDL may include openings disposed in the display area DA and corresponding to the light emitting areas EA.

In FIGS. 4 and 5 that the areas corresponding to the openings of the pixel defining layer PDL are the light emitting areas EA, but the embodiments are not limited thereto. For example, each light emitting area EA may include an area where the pixel defining layer PDL is opened in an area corresponding to each pixel PX, and may further include an area where an edge portion of the pixel defining layer PDL is disposed around the area where the pixel defining layer PDL is opened.

At least one light emitting element ED may be disposed in each light emitting area EA. For example, a light emitting element ED of the first pixel PX1 may be disposed in the first light emitting area EA1, a light emitting element ED of the second pixel PX2 may be disposed in the second light emitting area EA2, and a light emitting element ED of the third pixel PX3 may be disposed in the third light emitting area EA3.

In an embodiment, each of the pixels PX may further include a pixel circuit area in which the pixel circuit (for example, the pixel circuit PXC in FIG. 3) connected to the light emitting element ED is disposed. The light emitting area EA of each pixel PX and the pixel circuit area may or may not overlap each other. The arrangement form or direction of the light emitting areas EA and the pixel circuit areas of the pixels PX arranged in the unit pixel area UPA may be substantially the same or different from each other.

The shapes and sizes of the light emitting areas EA disposed in the unit pixel area UPA may be the same or different from each other. For example, as illustrated in FIG. 4, the shapes and sizes of the first light emitting area EA1, the second light emitting area EA2, and the third light emitting area EA3 may be substantially the same. As an example, the first light emitting area EA1, the second light emitting area EA2, and the third light emitting area EA3 may have a rectangular planar shape and may have substantially the same or similar size. By way of example, as illustrated in FIG. 5, the shapes and/or sizes of at least two light emitting areas EA of the first light emitting area EA1, the second light emitting area EA2, and the third light emitting area EA3 may be different from each other. As an example, the third light emitting area EA3 may have a horizontally long rectangular shape, and the first light emitting area EA1 and the second light emitting area EA2 may have a vertically long rectangular shape. The first light emitting area EA1, the second light emitting area EA2, and the third light emitting area EA3 may have round corners or angled corners. The size of the third light emitting area EA3 may be smaller than the size of each of the first light emitting area EA1 and the second light emitting area EA2. The shape or size (or ratio) of the light emitting areas EA may vary depending on the embodiments.

The first pixel PX1, the second pixel PX2, and the third pixel PX3 may emit light of a first color, light of a second color, and light of a third color, respectively. In an embodiment, the light of the first color, the light of the second color, and the light of the third color may be red light, green light, and blue light, respectively, but are not limited thereto.

In an embodiment, the first pixel PX1, the second pixel PX2, and the third pixel PX3 may include a first light emitting element (for example, a red light emitting element) that emits light of a first color, a second light emitting element (for example, a green light emitting element) that emits light of a second color, and a third light emitting element (for example, a blue light emitting element) that emits light of a third color. By way of example, the first pixel PX1, the second pixel PX2, and the third pixel PX3 may include light emitting elements ED (for example, blue light emitting elements or white light emitting elements) that emit light of the same color, and at least one of a wavelength conversion layer (for example, a wavelength conversion layer including quantum dots) for converting the color or wavelength of light emitted from the light emitting element ED of the pixel PX into another color or wavelength and a color filter layer may be further disposed in the light emitting area EA of at least one pixel PX of the first pixel PX1, the second pixel PX2, and the third pixel PX3.

In the above-described embodiments, the number or type of pixels PX forming each unit pixel UPX may be changed in various ways. As an example, the unit pixel UPX may also include four or more pixels PX. The four or more pixels PX may emit light of different colors (for example, red, green, blue, and white), or at least two of the four or more pixels PX may emit light of the same color.

In an embodiment, a spacer SPC may be further disposed in the display area DA. The spacer SPC may be disposed on a portion of the pixel defining layer PDL. The spacer SPC may be integral with the pixel defining layer PDL or may be formed on the pixel defining layer PDL after the pixel defining layer PDL is formed.

In an embodiment, spacers SPC separated from each other may be disposed in the display area DA. The spacers SPC may be distributed in the display area DA at uniform or non-uniform intervals or in an arrangement form, and may be disposed in the non-light emitting area around the light emitting areas EA. The size, shape, arrangement spacing, or arrangement form of the spacers SPC may vary depending on the embodiments.

In an embodiment, at least one spacer SPC may be disposed between two light emitting areas EA adjacent to each other in the first direction D1 and/or the second direction D2. As an example, the spacer SPC may be disposed between the first light emitting area EA1 and the second light emitting area EA2 adjacent to each other in the first direction D1 in at least one unit pixel area UPA. In an embodiment, the spacer SPC may have a rectangular planar shape extending in the second direction D2, etc., and may include round or angled corners. By way of example, the spacer SPC may also have various planar shapes other than the rectangular shape, such as a polygonal shape or a circular shape. Each spacer SPC may be positioned in any one unit pixel area UPA, between the unit pixel areas UPA adjacent to each other, or at an edge of the display area DA.

FIG. 6 is a schematic cross-sectional view illustrating a display panel according to an embodiment. For example, FIG. 6 illustrates an example of a cross section of a portion of the display area DA corresponding to lines X1 to X1′ in FIG. 5. FIG. 6 illustrates a light emitting display panel including a light emitting element ED (for example, an organic light emitting diode), as an example of the display panel 110 to which the embodiments may be applied.

Referring to FIG. 6, the display panel 110 according to an embodiment may include a substrate SUB, a panel circuit layer PCL, a light emitting element layer LEL, and a protective layer PRL. In an embodiment, the display panel 110 may further include a filler FIL filled between the light emitting element layer LEL and the protective layer PRL.

The panel circuit layer PCL, the light emitting element layer LEL, the filler FIL, and the protective layer PRL may be disposed to overlap each other on the substrate SUB. As an example, in the display area DA, the panel circuit layer PCL, the light emitting element layer LEL, the filler FIL, and the protective layer PRL may be sequentially disposed on the substrate SUB along the third direction D3.

The substrate SUB, which is a base member for forming the display panel 110, may be a rigid or flexible substrate (or film). The substrate SUB may be a lower substrate SUB1 of the display panel 110.

The substrate SUB may include a display area DA in which pixels PX are disposed. The display area DA may include light emitting areas EA of the pixels PX and a non-light emitting area NEA around the light emitting areas EA. The light emitting areas EA may be areas where the light emitting elements ED of the pixels PX are disposed, and may be areas where light generated from the light emitting elements ED is emitted. The non-light emitting area NEA may be disposed between and/or around the light emitting areas EA. For example, the non-light emitting area NEA may have a shape surrounding the light emitting areas EA in plan view, and may be disposed around the light emitting areas EA.

In an embodiment, the substrate SUB may be a substrate that may include an insulating material such as glass and has rigid characteristics and may not be bent. By way of example, the substrate SUB may be a flexible substrate that may include polyimide or another insulating material and is capable of deformation such as bending, folding, or rolling, and may or may not be bent. The type and/or material of the substrate SUB may be changed depending on the embodiments.

A panel circuit layer PCL (for example, a pixel circuit layer or a thin film transistor layer) may be disposed on the substrate SUB. The panel circuit layer PCL may include circuit elements (for example, the transistors T and capacitor Cst in FIG. 3) constituting the pixel circuit PXC of each pixel PX and lines (for example, signal lines and power lines). In an embodiment, the panel circuit layer PCL may further include circuit elements (for example, driver transistors and/or driver capacitors provided to the first driver 120) of the first driver 120. In an embodiment, the transistors T disposed on the panel circuit layer PCL may be thin film transistors TFT formed through a thin film deposition process or the like within the spirit and the scope of the disclosure.

FIG. 6 illustrates one thin film transistor TFT as an example of the circuit elements disposed in each pixel area in the panel circuit layer PCL. The thin film transistor TFT in FIG. 6 may be a driving transistor (for example, the first transistor T1 in FIG. 3) or a switching transistor (for example, the second transistor T2 or the third transistor T3 in FIG. 3) provided in the pixel circuit PXC of the corresponding pixel PX.

In an embodiment, the panel circuit layer PCL may include a barrier layer BR. As an example, the barrier layer BR may be disposed on the substrate SUB, and the circuit elements and the lines may be disposed on the barrier layer BR.

The panel circuit layer PCL may include conductive layers and at least one semiconductor layer SCL disposed on the barrier layer BR. Electrodes constituting the circuit elements of the panel circuit layer PCL, conductive patterns (for example, bridge electrodes) connected to the circuit elements, and/or lines may be disposed or included in the conductive layers. Active layers ACT of the thin film transistors TFT disposed inside the panel circuit layer PCL may be disposed or included in the semiconductor layer SCL.

In an embodiment, the panel circuit layer PCL may include a first conductive layer CDL1 (for example, a bottom conductive layer), a semiconductor layer SCL (for example, an oxide semiconductor layer or a poly-silicon semiconductor layer), a second conductive layer CDL2 (for example, a gate conductive layer), and a third conductive layer CDL3 (for example, a source-drain conductive layer or a data conductive layer) that are sequentially disposed on the barrier layer BR (or the substrate SUB) along the third direction D3. Insulating layers and/or insulating patterns may be disposed between the conductive layers and the semiconductor layer SCL of the panel circuit layer PCL.

The patterns (for example, electrodes, conductive patterns, and/or lines of each conductive layer) included in each conductive layer of the panel circuit layer PCL may include at least one conductive material. For example, the patterns included in each of the first conductive layer CDL1, the second conductive layer CDL2, and the third conductive layer CDL3 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), and other metals, an alloy thereof, or other conductive materials.

In an embodiment, each pattern included in each conductive layer of the panel circuit layer PCL may have a single-layer or multi-layer structure. For example, the patterns disposed or included in the first conductive layer CDL1, the second conductive layer CDL2, and the third conductive layer CDL3, respectively, may have a single-layer or multi-layer structure. In an embodiment, patterns of the same conductive layer may be formed simultaneously using the same material and may have the same cross-section structure.

The panel circuit layer PCL may further include insulating layers and/or insulating patterns disposed on the substrate SUB. For example, the panel circuit layer PCL may include a barrier layer BR, a first insulating layer INS1 (for example, a buffer layer), a gate insulating layer GI, a second insulating layer INS2 (for example, an interlayer insulating layer), a third insulating layer INS3 (for example, a passivation layer), and a fourth insulating layer INS4 (for example, a planarization layer) that are sequentially disposed on the substrate SUB along the third direction D3.

In an embodiment, at least one insulating layer provided in the panel circuit layer PCL may be entirely disposed in the display area DA. For example, the barrier layer BR, the first insulating layer INS1, the second insulating layer INS2, the third insulating layer INS3, and the fourth insulating layer INS4 may be entirely disposed in the display area DA.

The gate insulating layer GI may be partially disposed only in each pixel area and a portion of the display area DA including the same, or may be entirely disposed in the display area DA. In the embodiment of FIG. 6, the gate insulating layer GI may be partially disposed only in each pixel area and a portion of the display area DA including the same.

The barrier layer BR may be disposed between the substrate SUB and the first conductive layer CDL1. The barrier layer BR may include at least one inorganic insulating layer including an inorganic insulating material (for example, silicon nitride, silicon oxide, silicon oxynitride, titanium oxide, aluminum oxide, or other inorganic insulating materials). The barrier layer BR may protect the pixels PX from moisture permeating through the substrate SUB that is vulnerable to moisture permeation. The material of the barrier layer BR may vary depending on the embodiments.

The first insulating layer INS1 may be disposed on the first conductive layer CDL1. For example, the first insulating layer INS1 may be disposed on the barrier layer BR (or the substrate SUB) and cover the patterns of the first conductive layer CDL1. The first insulating layer INS1 may include at least one inorganic insulating layer including an inorganic insulating material (for example, silicon nitride, silicon oxide, silicon oxynitride, titanium oxide, aluminum oxide, or other inorganic insulating materials).

The gate insulating layer GI may be disposed on the semiconductor layer SCL. The gate insulating layer GI may include at least one inorganic insulating layer including an inorganic insulating material.

In an embodiment, the gate insulating layer GI may be disposed on only a portion of the semiconductor layer SCL. For example, the gate insulating layer GI may be partially disposed on the active layer ACT included in each thin film transistor TFT. As an example, the gate insulating layer GI may be disposed only on a portion of the active layer ACT including the channel region CH, and may expose another portion of the active layer ACT including at least a portion of each of the source region SR and the drain region DR.

As the gate insulating layer GI exposes the source region SR and drain region DR, the source region SR and drain region DR may be appropriately and/or readily made conductive during the manufacturing process of the display panel 110. For example, in the step of etching the gate insulating layer GI to expose at least a portion of each of the source region SR and the drain region DR, oxygen-vacancy may occur in the source region SR and drain region DR. Accordingly, without performing a separate doping process, the source region SR and drain region DR may be appropriately made conductive in a subsequent process (for example, a process of forming the second insulating layer INS2, etc.).

The second insulating layer INS2 may be disposed on the first insulating layer INS1, the semiconductor layer SCL, the gate insulating layer GI, and the second conductive layer CDL2. For example, the second insulating layer INS2 may be disposed on the first insulating layer INS1, and cover patterns of the semiconductor layer SCL, the gate insulating layer GI, and the second conductive layer CDL2. The second insulating layer INS2 may include at least one inorganic insulating layer including an inorganic insulating material.

The third insulating layer INS3 may be disposed on the third conductive layer CDL3. For example, the third insulating layer INS3 may be disposed on the second insulating layer INS2 and cover patterns of the third conductive layer CDL3. The third insulating layer INS3 may include at least one inorganic insulating layer including an inorganic insulating material.

In an embodiment, the display panel 110 may not include the third insulating layer INS3. For example, the fourth insulating layer INS4 may be disposed directly on the second insulating layer INS2 and the third conductive layer CDL3.

The fourth insulating layer INS4 may be disposed on the third insulating layer INS3 (or third conductive layer CDL3). The fourth insulating layer INS4 may include at least one organic insulating layer including an organic insulating material (for example, acrylic resin, epoxy resin, phenolic resin, polyamide resin, polyimide resin, or other organic insulating materials). A surface (for example, an upper surface) of the fourth insulating layer INS4 may be substantially flat.

The thin film transistor TFT may include an active layer ACT and a gate electrode GE overlapping the active layer ACT. In an embodiment, the gate electrode GE may be disposed on a portion of the active layer ACT. For example, the gate electrode GE may be a top-gate electrode.

In an embodiment, the thin film transistor TFT may further include at least one of a source electrode SE and a drain electrode DE. For example, the thin film transistor TFT may further include a source electrode SE connected to the source region SR and a drain electrode DE connected to the drain region DR. By way of example, the thin film transistor TFT may not include a separate source electrode and/or drain electrode, and the source region SR and/or drain region DR may be connected to other circuit elements, lines, and/or conductive patterns to function as the source electrode and/or the drain electrode of the thin film transistor TFT.

In an embodiment, the thin film transistor TFT may further include a bottom electrode BE (or a light blocking layer) disposed below the active layer ACT. In an embodiment, the bottom electrode BE may be connected to one electrode (for example, source electrode SE) of the thin film transistor TFT, and may be utilized as a back-gate electrode (or bottom-gate electrode) to adjust characteristics of the thin film transistor TFT. As an example, the bottom electrode BE may be electrically connected to the source electrode SE of the thin film transistor TFT through at least one contact hole penetrating through the first insulating layer INS1 and the second insulating layer INS2. By disposing the bottom electrode BE below the active layer ACT, it is possible to block external light from entering the channel region CH and stabilize operating characteristics of the thin film transistor TFT.

In an embodiment, the thin film transistor TFT may be an oxide transistor including an oxide semiconductor. As an example, the thin film transistor TFT may be an N-type oxide transistor. However, the embodiments are not limited thereto. For example, at least one transistor T included in the pixel circuit PXC may also be formed of other semiconductor materials (for example, amorphous silicon or polysilicon) other than the oxide semiconductor.

In an embodiment, the transistors T included in the pixel circuit PXC may be thin film transistors TFT including the same type of semiconductor material, or may be thin film transistors TFT including at least two different types of semiconductor materials. In an embodiment, in case that the pixel circuit PXC includes the thin film transistors TFT including different semiconductor materials, the panel circuit layer PCL may include semiconductor layers SCL, and the active layers ACT of the thin film transistors TFT may be disposed in different semiconductor layers SCL in the panel circuit layer PCL.

The bottom electrode BE may be disposed or included in the first conductive layer CDL1. For example, the bottom electrode BE may be disposed between the barrier layer BR (or the substrate SUB) and the first insulating layer INS1.

The bottom electrode BE may overlap the active layer ACT and the gate electrode GE. For example, the bottom electrode BE may be disposed below the active layer ACT to overlap at least a portion of the active layer ACT including the channel region CH, and may face the gate electrode GE with the active layer ACT disposed therebetween.

The active layer ACT may be disposed or included in the semiconductor layer SCL. For example, the active layer ACT may be disposed on the first insulating layer INS1, and at least a portion of the active layer ACT may be covered with the gate insulating layer GI.

The active layer ACT may include a channel region CH, and a source region SR and a drain region DR spaced apart from each other with the channel region CH disposed therebetween. For example, the source region SR and the drain region DR may be positioned at sides (e.g., opposite sides) of the channel region CH. The source region SR and drain region DR may have a higher carrier concentration (for example, electron concentration) than the channel region CH.

The active layer ACT may overlap the bottom electrode BE and the gate electrode GE. For example, a portion of the active layer ACT including the channel region CH may overlap the bottom electrode BE and the gate electrode GE in the third direction D3.

In an embodiment, the active layer ACT may include an oxide semiconductor. For example, the active layer ACT may include an oxide semiconductor including at least one of indium (In), gallium (Ga), zinc (Zn), tin (Sn), and hafnium (Hf), or other oxide semiconductors. As an example, the active layer ACT may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), and indium-tin-gallium-zinc oxide (ITGZO), or other oxide semiconductors.

However, the embodiments are not limited thereto. For example, the active layer ACT may also be formed of other semiconductor materials (for example, amorphous silicon or polysilicon) other than the oxide semiconductor.

A gate insulating layer GI may be disposed on the active layer ACT. For example, the gate insulating layer GI may be disposed on a portion of the active layer ACT including the channel region CH.

A gate electrode GE may be disposed on the gate insulating layer GI. For example, the gate electrode GE may be disposed on the gate insulating layer GI in the area where the thin film transistor TFT is disposed. The gate electrode GE may be disposed or included in the second conductive layer CDL2. The second conductive layer CDL2 may be disposed on the gate insulating layer GI and covered with the second insulating layer INS2.

The gate electrode GE may be disposed on the active layer ACT. For example, the gate electrode GE may be disposed on the gate insulating layer GI covering the channel region CH. The gate electrode GE and the active layer ACT may be separated from each other with the gate insulating layer GI disposed therebetween.

The source electrode SE and the drain electrode DE may be disposed or included in the third conductive layer CDL3. The third conductive layer CDL3 may be disposed on the second insulating layer INS2 covering the second conductive layer CDL2, etc., and covered with the third insulating layer INS3 and/or the fourth insulating layer INS4.

The source electrode SE may be connected to a portion of the active layer ACT. For example, the source electrode SE may be electrically connected to the source region SR through at least one contact hole penetrating through the second insulating layer INS2. In an embodiment, the source electrode SE may also be electrically connected to the bottom electrode BE through at least one contact hole penetrating through the first insulating layer INS1 and the second insulating layer INS2.

The drain electrode DE may be connected to another portion of the active layer ACT. For example, the drain electrode DE may be electrically connected to the drain region DR through at least one contact hole penetrating through the second insulating layer INS2.

At least one thin film transistor TFT included in each pixel PX may be electrically connected to a light emitting element ED of the corresponding pixel PX. For example, one electrode (for example, the source electrode SE) of the thin film transistor TFT included in the first pixel PX1 may be electrically connected to a first electrode ET1 of a first light emitting element ED1 disposed in the first light emitting area EA1, and one electrode (for example, the source electrode SE) of the thin film transistor TFT included in the second pixel PX2 may be electrically connected to a first electrode ET1 of a second light emitting element ED2 disposed in the second light emitting area EA2. In the same way, one electrode of the thin film transistor TFT included in the third pixel PX3 may be electrically connected to a third light emitting element disposed in the third light emitting area EA3.

A light emitting element layer LEL may be disposed on the panel circuit layer PCL including the thin film transistors TFT. For example, the light emitting element layer LEL may be disposed on the fourth insulating layer INS4.

The light emitting element layer LEL may include the light emitting element of each of the pixels PX. For example, the light emitting element layer LEL may include a pixel defining layer PDL (also referred to as a “bank”) that partitions the light emitting area of each of the pixels PX and a light emitting element ED positioned in each light emitting area. In an embodiment, the light emitting element layer LEL may further include a spacer SPC disposed on a portion of the pixel defining layer PDL.

The light emitting element ED may include a first electrode ET1 positioned in each light emitting area EA, and at least one light emitting layer EML and a second electrode ET2 sequentially disposed on the first electrode ET1. In an embodiment, the light emitting element ED may have a tandem structure including light emitting layers EML disposed on the first electrode ET1 and at least one intermediate layer IML disposed between the light emitting layers EML. As an example, the first light emitting element ED1 may include a first electrode ET1 disposed in the first light emitting area EA1, and a first light emitting layer EMLIA, an intermediate layer IML, a second light emitting layer EMLIB, and a second electrode ET2 sequentially disposed on the first electrode ET1, and the second light emitting element ED2 may include a first electrode ET1 disposed in the second light emitting area EA2, and a first light emitting layer EML2A, an intermediate layer IML, a second light emitting layer EML2B, and a second electrode ET2 sequentially disposed on the first electrode ET1. Similarly, the third light emitting element of the third pixel PX3 may include a first electrode disposed in the third light emitting area EA3, and a first light emitting layer, an intermediate layer IML, a second light emitting layer, and a second electrode ET2 sequentially disposed on the first electrode. However, the embodiments are not limited thereto. For example, at least one light emitting element ED may also include a single light emitting layer EML.

The first electrode ET1 of the light emitting element ED may be disposed on the fourth insulating layer INS4. The first electrode ET1 of the light emitting element ED may be connected to at least one thin film transistor TFT included in the corresponding pixel PX.

The first electrode ET1 of the light emitting element ED may be a single-layer or multi-layer electrode including at least one conductive material. In an embodiment, the display panel 110 may be a front-emitting display panel, and the first electrode ET1 may include a reflective electrode layer including a material (for example, metal) with high reflectivity.

The light emitting layer EML of the light emitting element ED may include a high molecular or a low molecular material. For example, the light emitting layer EML may include a high molecular or low molecular organic material that emits light of a given color (for example, a first color, a second color, or a third color). The light emitted from the light emitting layer EML may contribute to displaying an image.

In an embodiment, the light emitting layers EML of the light emitting elements ED included in the first pixel PX1, the second pixel PX2, and the third pixel PX3 may be individually disposed in each light emitting area EA and may emit light of different colors. For example, the first and second light emitting layers EMLIA and EMLIB of the first light emitting element ED1 may be organic light emitting layers that emit light of the first color, and may include the same or different materials. The first and second light emitting layers EML2A and EML2B of the second light emitting element ED2 may be organic light emitting layers that emit light of the second color, and may include the same or different materials. The first and second light emitting layers of the third light emitting element may be organic light emitting layers that emit light of the third color, and may include the same or different materials.

However, the embodiments are not limited thereto. For example, in an embodiment, the light emitting layers EML of the light emitting elements ED included in the first pixel PX1, the second pixel PX2, and the third pixel PX3 may be entirely disposed in the display area DA in the form of a common film commonly formed in the pixels PX, and the color of light emitted from each pixel PX may be controlled or changed by disposing a light conversion layer or a color filter layer on the light emitting elements ED of the pixels PX.

The intermediate layer IML may be disposed between the first electrode ET1 and the second electrode ET2 of each of the light emitting elements ED, and may overlap the light emitting layer EML of each of the light emitting elements ED. The intermediate layer IML may include at least one of a charge generation layer, a hole injection layer, a hole transport layer, an electron injection layer, and an electron transport layer. As an example, the intermediate layer IML may include a charge generation layer. The intermediate layer IML may form an organic layer ORL of each of the light emitting elements ED together with the light emitting layer EML.

In an embodiment, the intermediate layer IML may be entirely disposed in the display area DA in the form of a common film commonly formed in the pixels PX. As an example, a portion of the intermediate layer IML passing through the non-light emitting area NEA may be disposed on the pixel defining layer PDL and the spacer SPC.

The second electrode ET2 of the light emitting element ED may include a conductive material. In an embodiment, the second electrode ET2 may be a common film disposed entirely in the display area DA in the form of covering the light emitting layers EML and the pixel defining layer PDL of the light emitting elements ED disposed in the display area DA. For example, the second electrode ET2 may be entirely disposed in the display area DA including the light emitting areas EA of the pixels PX and the non-light emitting area NEA around the light emitting areas EA. In an embodiment, the display panel 110 may be a front-emitting display panel, and the second electrode ET2 may include a transparent or semi-transparent electrode layer.

The pixel defining layer PDL may include openings corresponding to the light emitting areas EA and may surround the light emitting areas EA. In an embodiment, the pixel defining layer PDL may be formed to cover edge portions of the first electrodes ET1 of the light emitting element ED and may include openings that expose the remaining portions of the first electrodes ET1. An area where the first electrode ET1 of each of the light emitting elements ED and the light emitting layer EML overlap may correspond to the light emitting area EA of each pixel PX. In an embodiment, the pixel defining layer PDL may include at least one organic insulating layer including an organic insulating material.

The spacer SPC may be disposed on a portion of the pixel defining layer PDL. The spacer SPC may include at least one organic insulating layer including an organic insulating material. The spacer SPC may include the same material as the pixel defining layer PDL or may include a different material from the pixel defining layer PDL. The pixel defining layer PDL and the spacer SPC may be formed sequentially through each mask process, or may be formed simultaneously and/or integrally using a halftone mask.

The filler FIL may be disposed between the light emitting element layer LEL and the protective layer PRL. The filler FIL may include a material such as resin and may be optically transparent. The filler FIL may absorb shock applied to the display panel 110 and may maintain a uniform distance between the light emitting element layer LEL and the protective layer PRL.

The protective layer PRL may be disposed on one surface or a surface of the substrate SUB on which the panel circuit layer PCL and the light emitting element layer LEL are formed. For example, the protective layer PRL may be disposed on the light emitting element layer LEL and the filler FIL. In an embodiment, the substrate SUB and the protective layer PRL may be a lower substrate SUB1 and an upper substrate SUB2 of the display panel 110, respectively, and may be bonded to each other with the filler FIL disposed therebetween. In an embodiment, the protective layer PRL may include an insulating material such as glass and may have rigid properties, but is not limited thereto.

The display panel 110 according to the embodiment may include the spacers SPC disposed around the light emitting areas EA. As a result, a mask (for example, a fine metal mask including the openings corresponding to the light emitting areas EA) used in a process for forming the light emitting elements ED may be appropriately supported, and damage to the lower layer (for example, the pixel defining layer PDL disposed below a height of the spacer SPC or the light emitting layers EML of the light emitting elements ED, etc.) caused by the mask may be prevented or reduced. By using the spacer SPC, short circuit defects caused by conductive foreign substances may be prevented or reduced, and electrical stability of the pixels PX may be secured.

However, in case that impact is applied to the spacer SPC due to a collision between the mask and the spacer SPC in the process of manufacturing the display panel 110, damage such as scratches or cracks may occur in the spacer SPC. In case that the spacer SPC is damaged, a moisture permeable path may occur through which the filler FIL or moisture may permeate into the surrounding light emitting element ED. As an example, as illustrated in FIG. 6, in case that an impact is applied to the lower layer of the spacer SPC close to the pixel defining layer PDL, the impact may cause damage such as scratches or cracks to the spacer SPC, and the extent of the damage may expand over time. Accordingly, as the moisture permeable path through which the filler FIL or moisture may permeate into the light emitting element ED around the spacer SPC occurs, there is a risk of contaminating the light emitting element ED. In case that the light emitting element ED is contaminated, it may cause deterioration of the characteristics or a turn-off defect of the light emitting element ED. As a result, defects in the display panel 110 such as dark spots may occur.

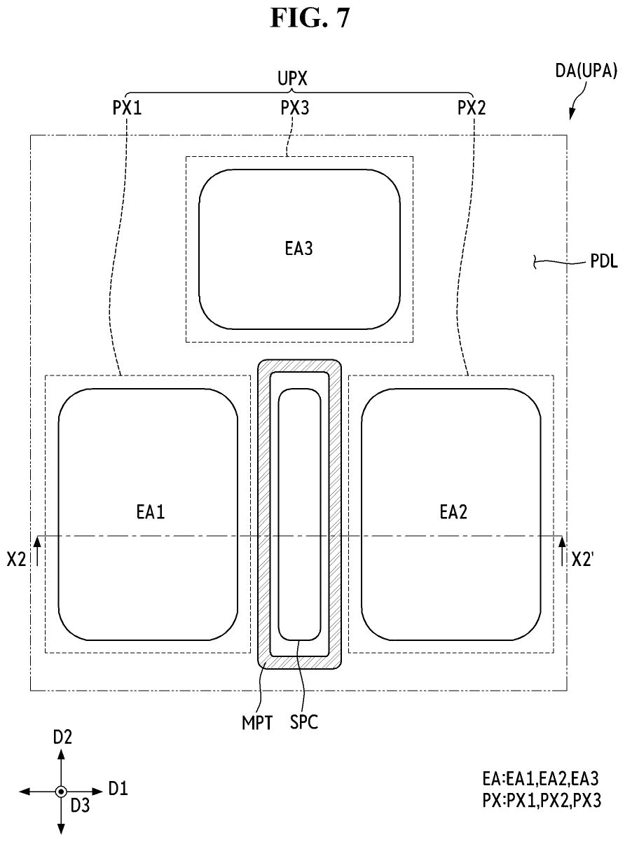

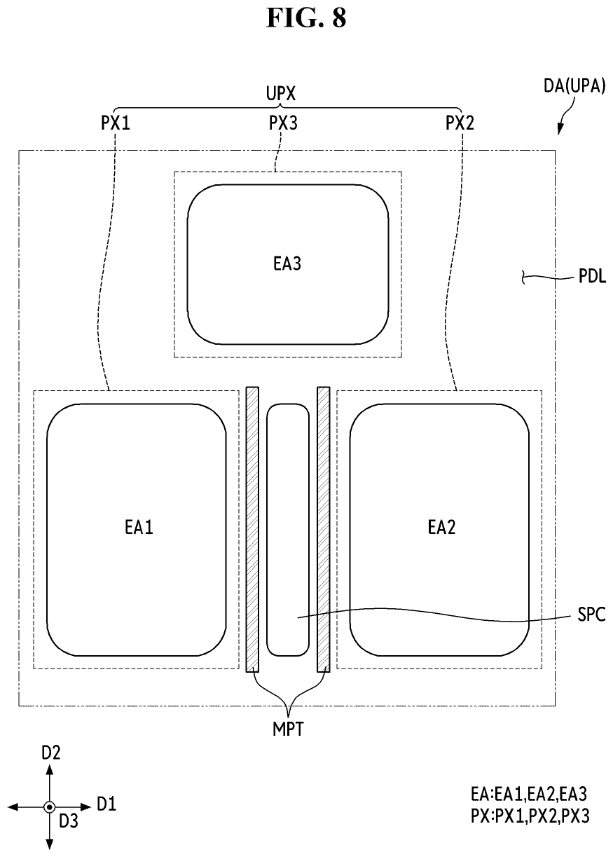

FIG. 7 is a schematic plan view illustrating a display area according to an embodiment. FIG. 8 is a schematic plan view illustrating a display area according to an embodiment. For example, FIGS. 7 and 8 illustrate a display area DA further including a second pattern MPT disposed around the spacer SPC compared to FIG. 5. FIGS. 7 and 8 illustrate different embodiments related to the second pattern MPT.

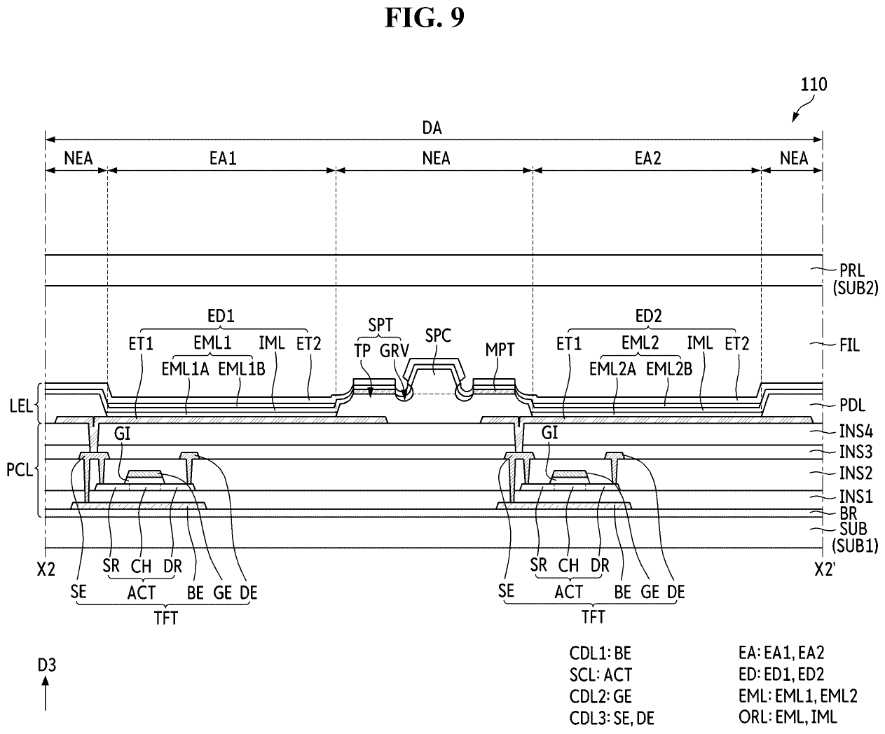

FIG. 9 is a schematic cross-sectional view illustrating a display panel according to an embodiment. For example, FIG. 9 illustrates an example of a cross section of a portion of the display area DA corresponding to lines X2 to X2′ in FIG. 7. FIG. 9 illustrates a display panel 110 further including a first pattern SPT and a second pattern MPT compared to FIG. 6.

In describing the following embodiments, the same reference numerals will be assigned to configurations that are substantially the same or similar to those in at least one embodiment described above, and redundant descriptions may be omitted. As an example, in describing the embodiments of FIGS. 7 to 9, detailed descriptions of the same or similar configurations as those of the embodiments of FIGS. 5 and 6 may be omitted.

Referring to FIGS. 7 to 9, the display panel 110 may further include a first pattern SPT and a second pattern MPT disposed around the spacer SPC. The first pattern SPT and the second pattern MPT may overlap each other.

In an embodiment, the first pattern SPT may be a pattern formed in (or formed on) the pixel defining layer PDL and having a level difference. As an example, the first pattern SPT may include a protrusion TP (referred to as a “tip”) disposed around the spacer SPC and a groove GRV around the protrusion TP. In FIG. 9, only one protrusion TP, groove GRV, and second pattern MPT are each indicated with reference numerals.

In an embodiment, the protrusion TP may overlap the second pattern MPT thereon. For example, an upper surface of the protrusion TP may be covered with the second pattern MPT.

The protrusion TP may be disposed at at least one side or a side of the spacer SPC. As an example, the protrusion TP may entirely or completely surround the spacer SPC, or may be separately disposed at sides (e.g., opposite sides) of the spacer SPC, when viewed from a plane (for example, a plane defined by the first direction D1 and the second direction D2). By way of example, the protrusion TP may be disposed at only one side or a side (for example, left or right) of the spacer SPC.

In an embodiment, the protrusion TP may have a shape corresponding to the shape of the spacer SPC. As an example, in case that the spacer SPC has a planar shape such as a rectangular shape including a long side extending in the second direction D2, the protrusion TP may have a shape extending at least in the second direction D2. As an example, the protrusion TP may have a ring shape having a band or line shape extending in the second direction D2 and disposed at sides of the spacer SPC, or having an opening corresponding to the spacer SPC and entirely surrounding the spacer SPC. The shapes of the spacer SPC and the protrusion TP may vary depending on the embodiments.

In an embodiment, the protrusion TP may be disposed between the light emitting areas EA adjacent to each other. As an example, the protrusion TP may be disposed between the first and second light emitting areas EA1 and EA2 that are adjacent to each other in the first direction D1. The position, shape, and/or arrangement of the protrusion TP may vary depending on the embodiments.

The groove GRV may be disposed at at least one side or a side of the protrusion TP. For example, the groove GRV may be disposed at sides of the protrusion TP (for example, the left and right sides of the protrusion TP), or may be entirely disposed around the protrusion TP. In an embodiment, the groove GRV may be formed only in the pixel defining layer PDL or may be formed in (or formed on) both the pixel defining layer PDL and the spacer SPC. As an example, the groove GRV may be a pattern formed by digging out at least one of the pixel defining layer PDL and the spacer SPC in a depth direction around the protrusion TP.

The first pattern SPT may be a separator pattern that causes a partial disconnection or level difference in a common film disposed or formed on the first pattern SPT. For example, at least one of the intermediate layer IML and the second electrode ET2 of the light emitting elements ED may be partially or locally disconnected or have a level difference around the first pattern SPT (for example, the top of the first pattern SPT) due to the level difference between the protrusion TP and the groove GRV of the first pattern SPT.

In an embodiment, a height difference (for example, a depth of the groove GRV) between the protrusion TP and the groove GRV of the first pattern SPT may be greater than or equal to a thickness of at least one common film (for example, the intermediate layer IML) disposed on the first pattern SPT, and accordingly, the at least one common film may be at least partially disconnected on the first pattern SPT. However, the embodiments are not limited thereto, and the protrusion TP and the groove GRV of the first pattern SPT may have a height difference sufficient to cause a level difference in the common film.

The second pattern MPT may be disposed on a portion of the first pattern SPT. For example, the second pattern MPT may be disposed on the protrusion TP of the first pattern SPT. The second pattern MPT may be a mask pattern used as a mask (for example, a hard mask) for forming the first pattern SPT in the manufacturing process of the display device 100 for manufacturing the display panel 110. In the display panel 110 including the second pattern MPT, the second pattern MPT, together with the first pattern SPT, may cause a partial disconnection (for example, a disconnection or isolation that locally occurs around the first pattern SPT and/or the second pattern MPT) or a level difference in the common film disposed on the second pattern MPT.

In an embodiment, the second pattern MPT may include a material suitable for use as a hard mask in a process (for example, an ashing process) for forming the first pattern SPT. For example, the second pattern MPT may include a metal or an oxide (for example, a metal oxide including ZIO, IGZO, or TIZO, or a non-metal oxide). The second pattern MPT may be formed to have a thickness that is suitable for use as a hard mask and/or may appropriately cause a partial disconnection or level difference in a film (for example, a common film passing over the pixel defining layer PDL and the spacer SPC) disposed thereon. As an example, the second pattern MPT may be formed of a metal film or an oxide film with a thickness of 200 to 500 Å, but is not limited thereto.

In case that the first pattern SPT is formed using the second pattern MPT as a hard mask, the first pattern SPT and the second pattern MPT may have shapes and/or sizes that correspond to each other. As an example, the second pattern MPT may completely cover the upper surface of the protrusion TP of the first pattern SPT, and the protrusion TP may have a shape (for example, a planar form) and/or a size corresponding to the shape (for example, the planar form) and/or the size of the second pattern MPT.

In an embodiment, the spacer SPC may be disposed between the first and second light emitting areas EA1 and EA2 that are adjacent to each other in the first direction D1, and may extend in the second direction D2 that intersects the first direction D1. The first pattern SPT may be formed in the pixel defining layer PDL and may be disposed at sides of the spacer SPC at least in the first direction D1. For example, the first pattern SPT may be disposed between the first light emitting area EA1 and the second light emitting area EA2, may be disposed at sides of the spacer SPC, or may surround the spacer SPC. As an example, the first pattern SPT may be disposed at sides of the spacer SPC in the first direction D1, or may entirely surround the spacer SPC when viewed on a plane defined by the first direction D1 and the second direction D2.

In an embodiment, in case that the first pattern SPT and the second pattern MPT have a shape that entirely surrounds the spacer SPC, a portion of the intermediate layer IML and/or the second electrode ET2 of the light emitting elements ED may be isolated in an island shape around the spacer SPC. Accordingly, the moisture permeation path around the spacer SPC may be blocked more appropriately or effectively. As a result, the light emitting element ED may be appropriately protected, and defects and performance degradation of the pixel PX may be prevented or reduced. Even if the intermediate layer IML and/or the second electrode ET2 of the light emitting elements ED are partially disconnected by the first pattern SPT, the second pattern MPT, etc., the intermediate layer IML and/or the second electrode ET2 of the light emitting elements ED may be entirely connected in the display area DA through the remaining portion. Accordingly, the light emitting elements ED may be appropriately driven.

In an embodiment, even if the first pattern SPT and the second pattern MPT do not entirely surround the spacer SPC, the path of leakage current through the common film such as the intermediate layer IML of the light emitting elements ED may be appropriately delayed or blocked. For example, by disposing the first pattern SPT and the second pattern MPT at sides of the spacer SPC disposed between the light emitting areas EA adjacent to each other, leakage current flowing between the light emitting elements ED disposed in the light emitting areas EA may be appropriately reduced or blocked. As a result, performance degradation (for example, luminance degradation) of the pixel PX due to the leakage current may be prevented and power consumption of the display device 100 may be improved.

At least one second pattern MPT may be disposed around each spacer SPC. As an example, as illustrated in FIG. 7, one second pattern MPT that completely surrounds the spacer SPC may be disposed around the spacer SPC. By way of example, as illustrated in FIG. 8, one second pattern MPT may be each disposed at sides of the spacer SPC. The two second patterns MPT disposed at sides of the spacer SPC may be separated or spaced apart from each other in the first direction D1.

The intermediate layer IML and the second electrode ET2 of the light emitting elements ED may be disposed on the first pattern SPT and the second pattern MPT in the non-light emitting area NEA. The intermediate layer IML and the second electrode ET2 of the light emitting elements ED may have a level difference corresponding to the first pattern SPT and the second pattern MPT, and may or may not be partially disconnected around the first pattern SPT and the second pattern MPT.

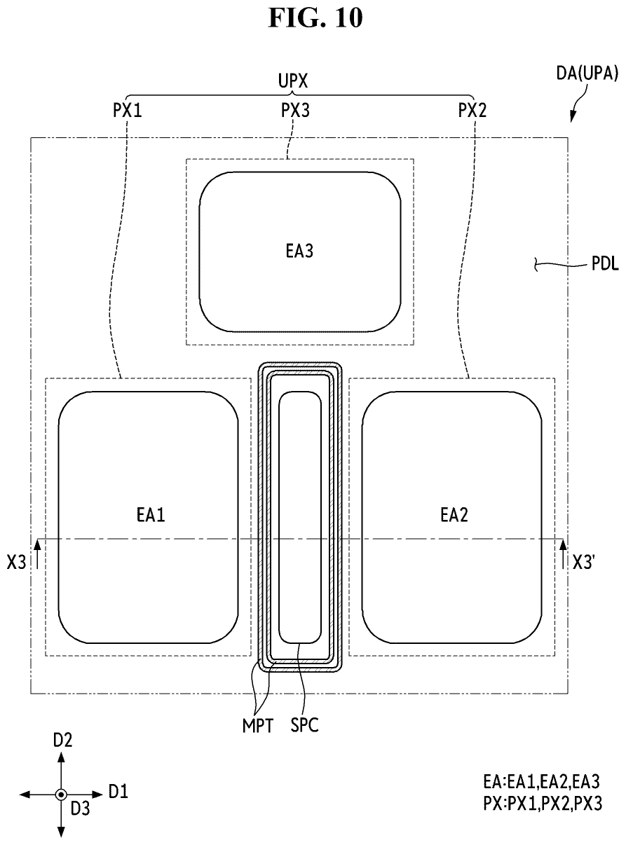

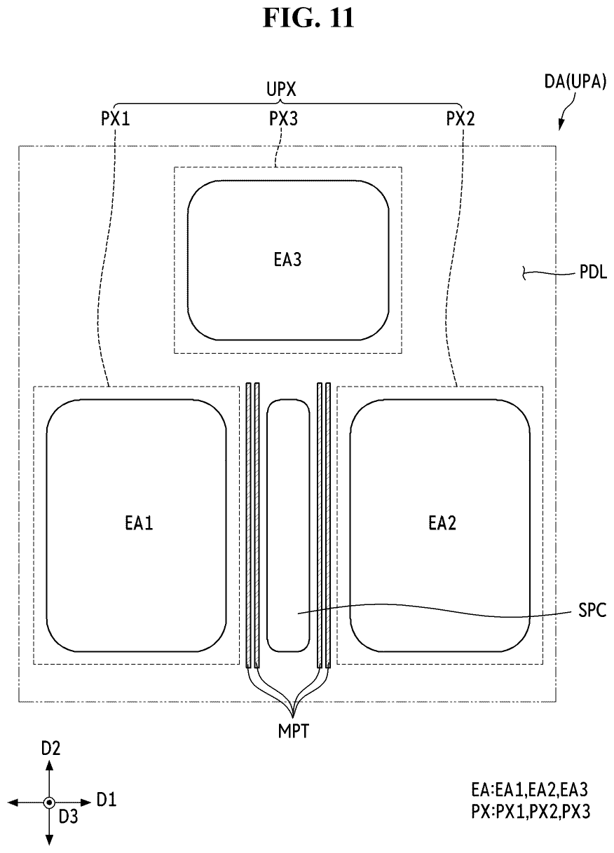

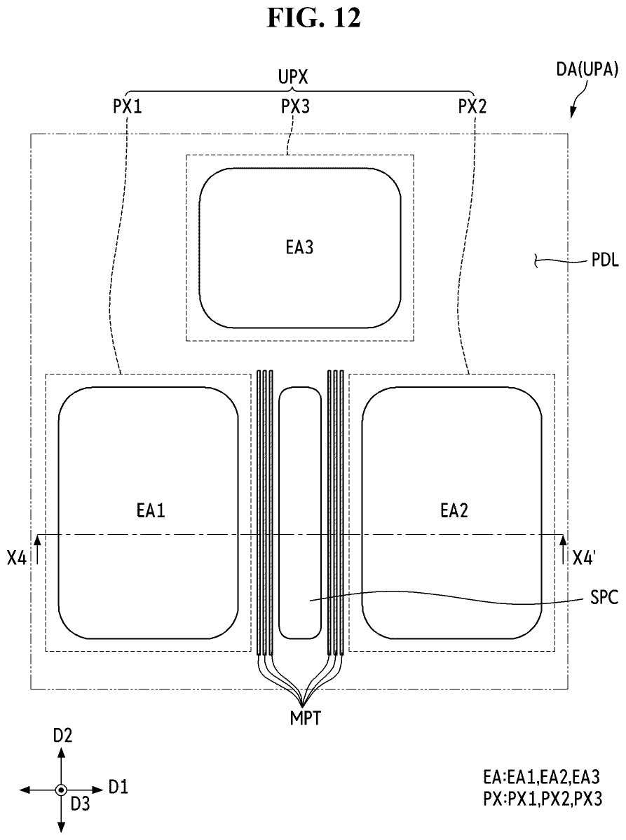

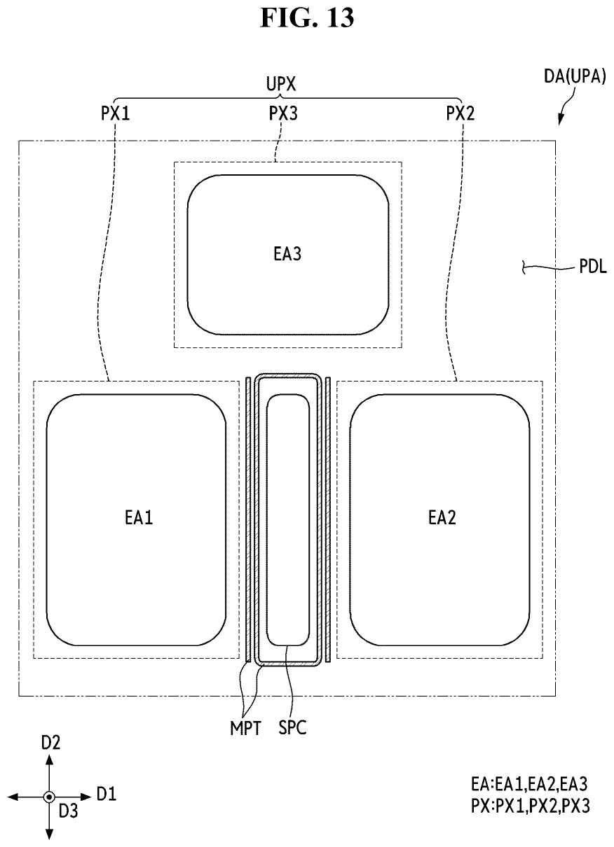

FIG. 10 is a schematic plan view illustrating a display area according to an embodiment. FIG. 11 is a schematic plan view illustrating a display area according to an embodiment. FIG. 12 is a schematic plan view illustrating a display area according to an embodiment. FIG. 13 is a schematic plan view illustrating a display area according to an embodiment. For example, FIGS. 10 to 13 illustrate embodiments that are different from the embodiments of FIGS. 7 and 8 with respect to the second pattern MPT.

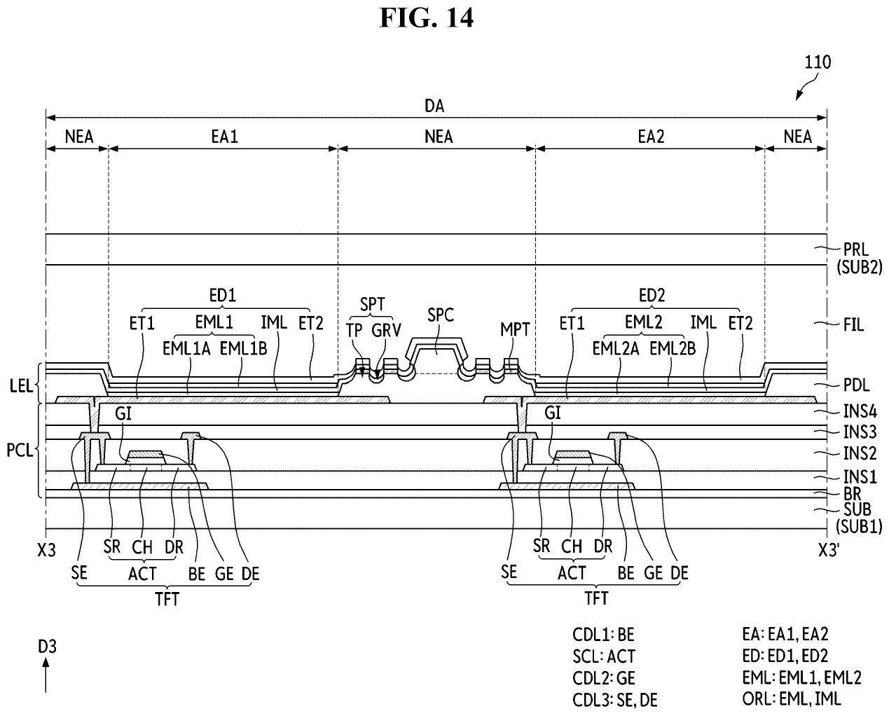

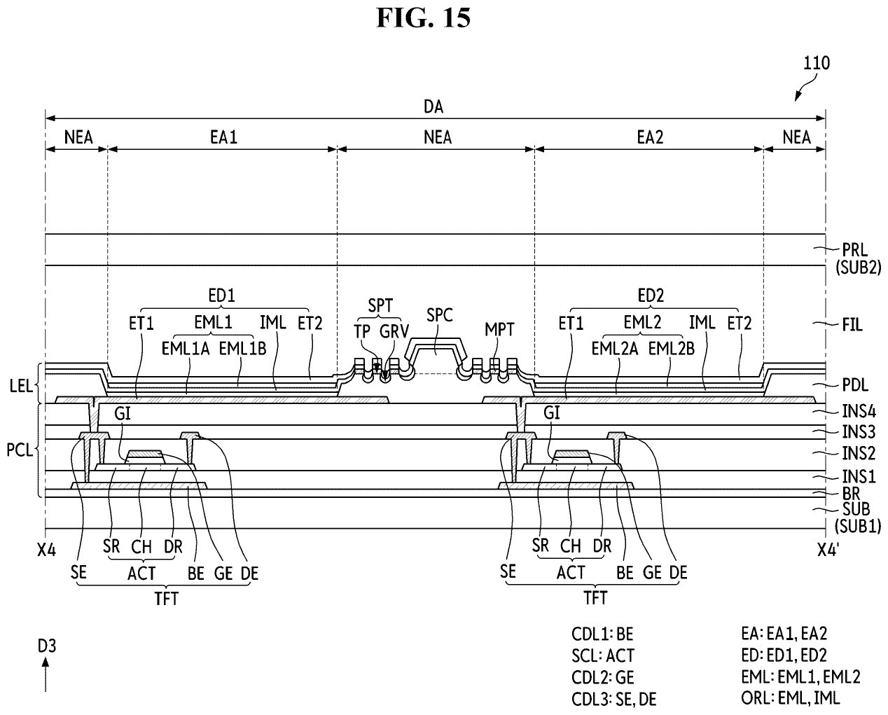

FIG. 14 is a schematic cross-sectional view illustrating a display panel according to an embodiment. FIG. 15 is a schematic cross-sectional view illustrating a display panel according to an embodiment. For example, FIG. 14 illustrates an example of a cross section of a portion of the display area DA corresponding to lines X3 to X3′ of FIG. 10, and FIG. 15 illustrates an example of a cross section of a portion of the display area DA corresponding to lines X4 to X4′ of FIG. 12.

Referring to FIGS. 10 to 15, the display panel 110 may include second patterns MPT disposed to be spaced apart from each other around the spacer SPC. As an example, as illustrated in FIG. 10, at least two second patterns MPT that sequentially surround the spacer SPC may be disposed around the spacer SPC. By way of example, as illustrated in FIGS. 11 and 12, at least two second patterns MPT (for example, two or three second patterns MPT) may be disposed at sides of the spacer SPC. The first pattern SPT formed in the pixel defining layer PDL may include protrusions TP disposed below each of the second patterns MPT and grooves GRV around the protrusions TP. By disposing the first patterns SPT and/or second patterns MPT between the light emitting areas EA adjacent to each other, moisture permeation or leakage current may be more effectively blocked or reduced.

In an embodiment, the second patterns MPT may have substantially the same planar shape or may have different planar shapes. As an example, the second patterns MPT may have substantially the same (or corresponding) shape as illustrated in FIGS. 10 to 12 or may have different planar shapes as illustrated in FIG. 13.

The shape, size, and/or number of the first patterns SPT and/or the second patterns MPT may vary depending on the embodiments. As an example, the position, shape, size, and/or number of the first patterns SPT and/or the second patterns MPT may vary depending on a width or area of the non-light emitting area NEA where the spacer SPC is disposed, the ease of processing, appropriateness or efficiency of a level difference or disconnection caused by the first patterns SPT and/or the second patterns MPT, etc.

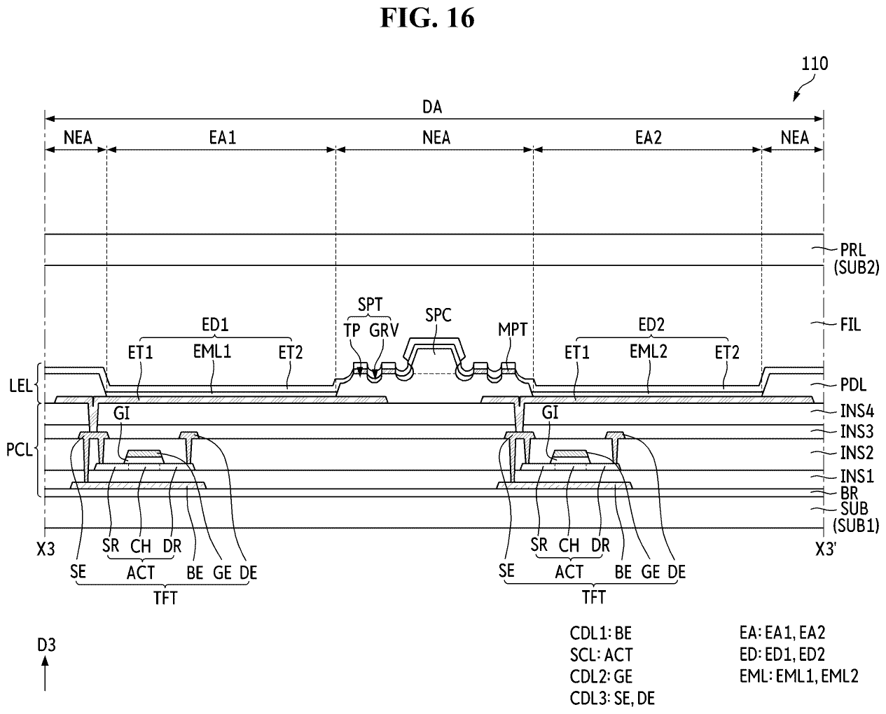

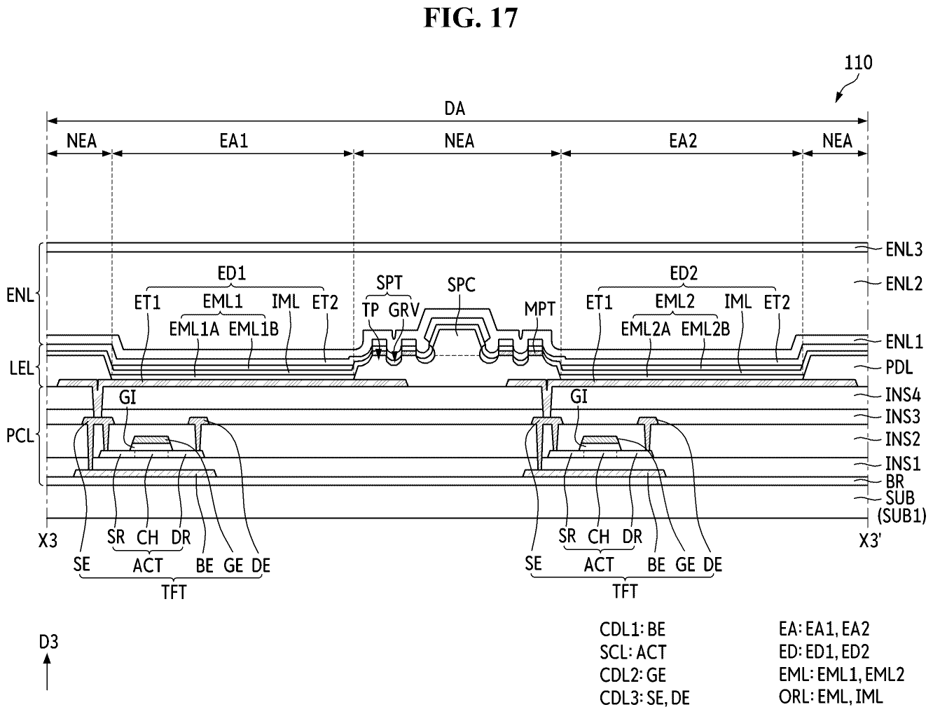

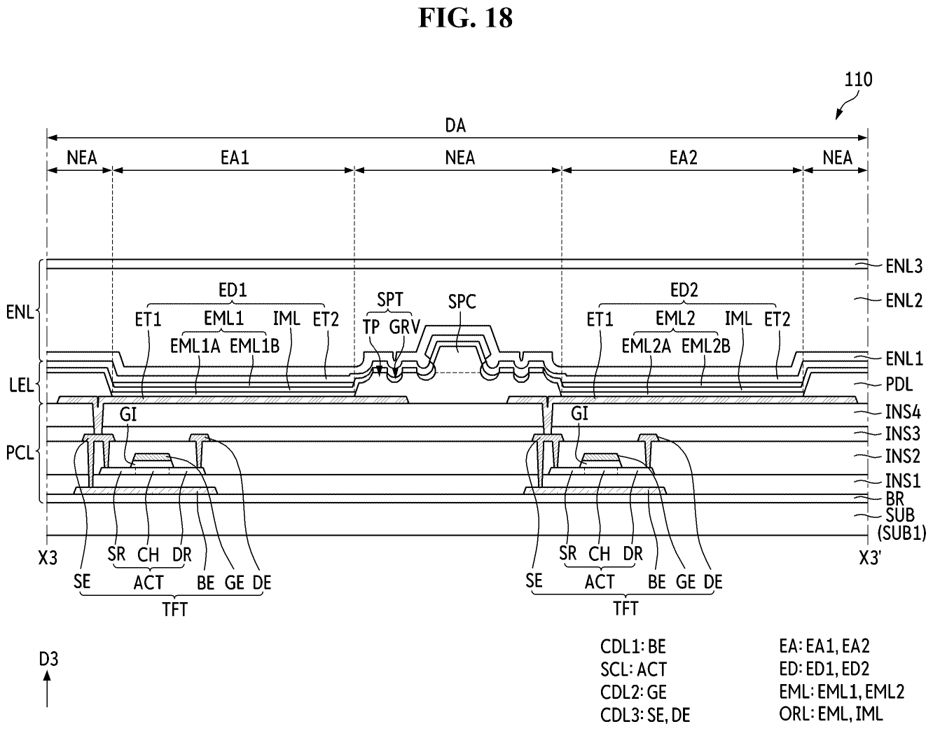

FIG. 16 is a schematic cross-sectional view illustrating a display panel according to an embodiment. FIG. 17 is a schematic cross-sectional view illustrating a display panel according to an embodiment. FIG. 18 is a schematic cross-sectional view illustrating a display panel according to an embodiment. For example, FIGS. 16 to 18 illustrate embodiments different from the embodiment of FIG. 14 with respect to the schematic cross-sectional of a portion of the display area DA corresponding to lines X3 to X3′ of FIG. 10.

Referring to FIG. 16, each light emitting element ED may include a single light emitting layer EML. As an example, the first light emitting element ED1 may include a first electrode ET1 disposed in the first emitting area EA1, a single first light emitting layer EML1 disposed on the first electrode ET1, and a second electrode ET2 disposed on the first light emitting layer EML1, and the second light emitting element ED2 may include a first electrode ET1 disposed in the second emitting area EA2, a single second light emitting layer EML2 disposed on the first electrode ET1, and a second electrode ET2 disposed on the second light emitting layer EML2. Similarly, the third light emitting element of the third pixel PX3 may include a first electrode disposed in the third light emitting area EA3, a single third light emitting layer disposed on the first electrode, and a second electrode ET2 disposed on the third light emitting layer. The light emitting elements ED may or may not include at least one intermediate layer (for example, the intermediate layer IML in FIG. 14).

Referring to FIG. 17, the display panel 110 may include an encapsulation layer ENL disposed on the light emitting element layer LEL. As an example, the display panel 110 may not include the filler FIL or the protective layer PRL of FIG. 15, and the light emitting element layer LEL may be encapsulated with the encapsulation layer ENL.

The encapsulation layer ENL may be disposed on the light emitting element layer LEL. The encapsulation layer ENL may cover the light emitting element layer LEL in the display area DA and extend to the non-display area NDA to be in contact with the panel circuit layer PCL. The encapsulation layer ENL may block the permeation of oxygen or moisture into the light emitting element layer LEL, and may alleviate electrical and/or physical shock to the panel circuit layer PCL and the light emitting element layer LEL.

In an embodiment, the encapsulation layer ENL may be a multi-layer encapsulation layer. For example, the encapsulation layer ENL may include a first encapsulation layer ENL1, a second encapsulation layer ENL2, and a third encapsulation layer ENL3 sequentially stacked each other on the light emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material.

Referring to FIG. 18, the display panel 110 may include only the first pattern SPT disposed around the spacer SPC and may not include the second pattern MPT. As an example, the second pattern MPT may be removed after being used as the mask pattern for forming the first pattern SPT. For example, the intermediate layer IML and/or the second electrode ET2 of the light emitting elements ED may be directly disposed on the first pattern SPT.

In case that the second pattern MPT is removed, the level difference of the common film formed on the pixel defining layer PDL and the spacer SPC may be alleviated. Accordingly, the encapsulation layer ENL may be more smoothly or appropriately formed on the common film. As an example, a level difference of the first encapsulation layer ENL1 may be alleviated, and the first encapsulation layer ENL1 may stably cover the light emitting element layer LEL.

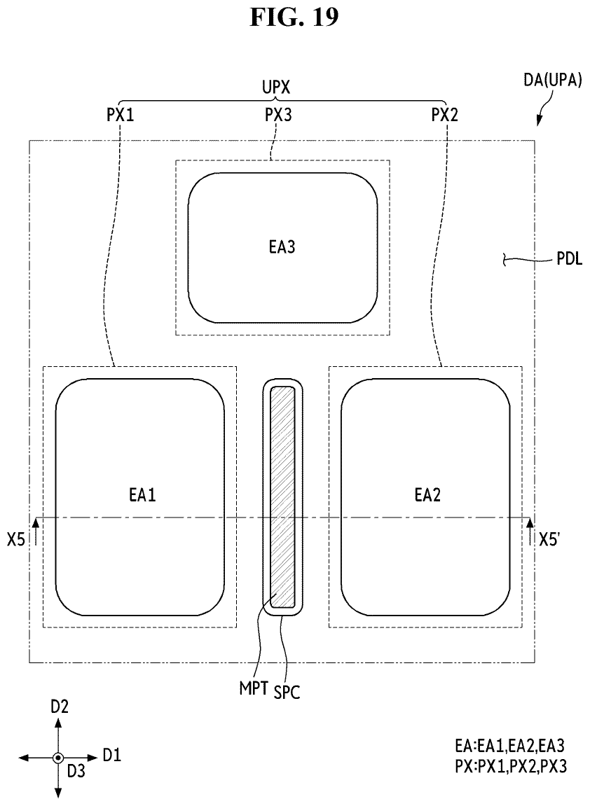

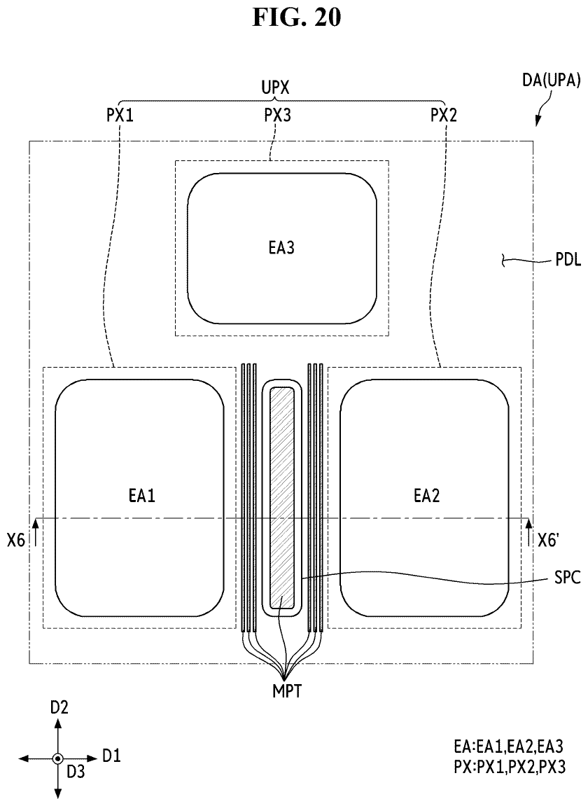

FIG. 19 is a schematic plan view illustrating a display area according to an embodiment. FIG. 20 is a schematic plan view illustrating a display area according to an embodiment. For example, FIGS. 19 and 20 illustrate embodiments that may be different from the embodiments of FIGS. 7 to 18 with respect to the second pattern MPT.

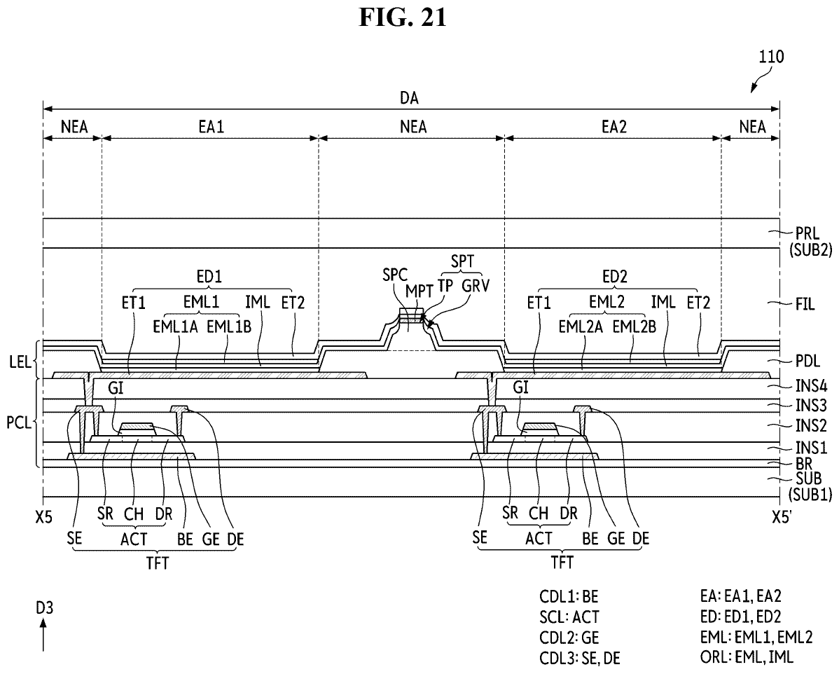

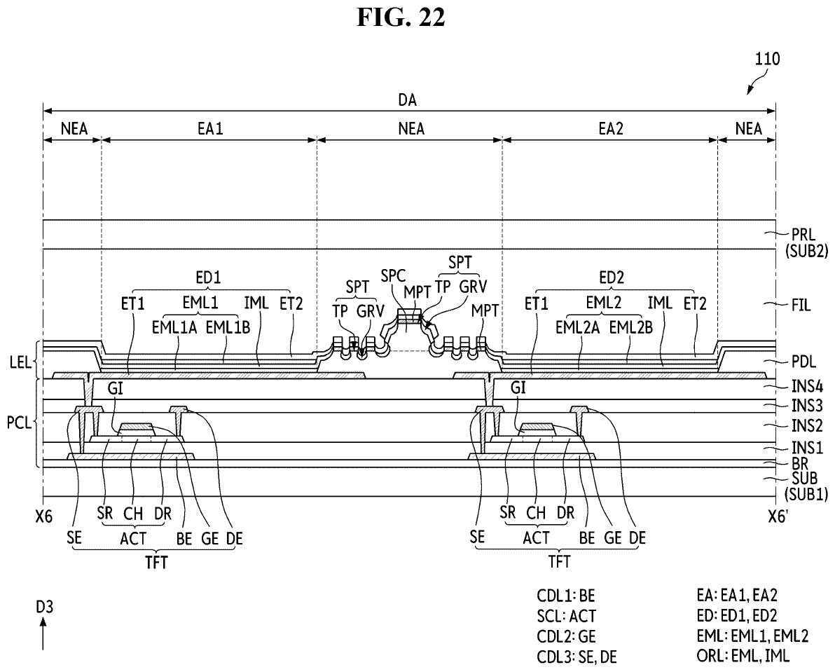

FIG. 21 is a schematic cross-sectional view illustrating a display panel according to an embodiment. FIG. 22 is a schematic cross-sectional view illustrating a display panel according to an embodiment. For example, FIG. 21 illustrates an example of a cross section of a portion of the display area DA corresponding to lines X5 to X5′ in FIG. 19. FIG. 22 illustrates an example of a cross section of a portion of the display area DA corresponding to lines X6 to X6′ in FIG. 20.

Referring to FIGS. 19 to 22, the display panel 110 may include at least one second pattern MPT disposed on the spacer SPC. For example, the display panel 110 may include a second pattern MPT disposed only on the spacer SPC, or may include second patterns MPT disposed on the pixel defining layer PDL and the spacer SPC. The first pattern SPT may be formed only in the spacer SPC, or may be formed in the pixel defining layer PDL and the spacer SPC.

In an embodiment in which the display panel 110 may include the second patterns MPT disposed on the pixel defining layer PDL and the spacer SPC, at least one second pattern MPT may be disposed on the pixel defining layer PDL and the spacer SPC, respectively. The second patterns MPT disposed on the pixel defining layer PDL and the spacer SPC may have the same or different shapes and/or sizes. In an embodiment, the second patterns MPT disposed on the pixel defining layer PDL and the spacer SPC may be separated from each other, but the embodiments are not limited thereto.

In an embodiment, the second pattern MPT may be removed after forming the first pattern SPT. For example, the display panel 110 may include only the first pattern SPT formed only in (or formed on) the spacer SPC or formed in (or formed on) the pixel defining layer PDL and the spacer SPC, and may not include the second pattern MPT.

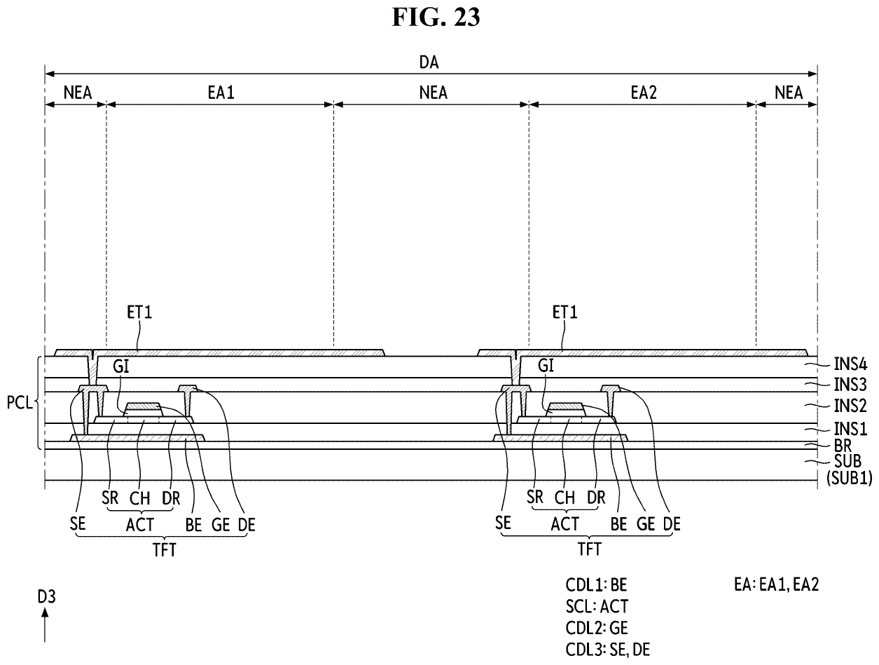

FIGS. 23 to 27 are schematic cross-sectional views illustrating a method of manufacturing a display device according to an embodiment. For example, FIGS. 23 to 27 sequentially illustrate manufacturing steps for manufacturing the display panel 110 according to the embodiment of FIG. 14. The display panels 110 according to other embodiments may also be manufactured in substantially the same or similar manner.

Referring to FIG. 23, a substrate SUB including light emitting areas EA and a non-light emitting area NEA may be prepared, and a first electrode ET1 of a light emitting element ED may be formed in each light emitting area EA on the substrate SUB. In an embodiment, a panel circuit layer PCL may be formed first on the substrate SUB, and the respective first electrodes ET1 may be formed in the light emitting areas EA on the panel circuit layer PCL. The first electrodes ET1 may be formed by being separated from each other in the light emitting areas EA by a process of forming a conductive film using at least one conductive material and an etching process of the conductive film. The first electrode ET1 and the thin film transistor TFT of each pixel PX may be electrically connected to each other through a contact hole penetrating through insulating layers (for example, a third insulating layer INS3 and a fourth insulating layer INS4) on the thin film transistor TFT.

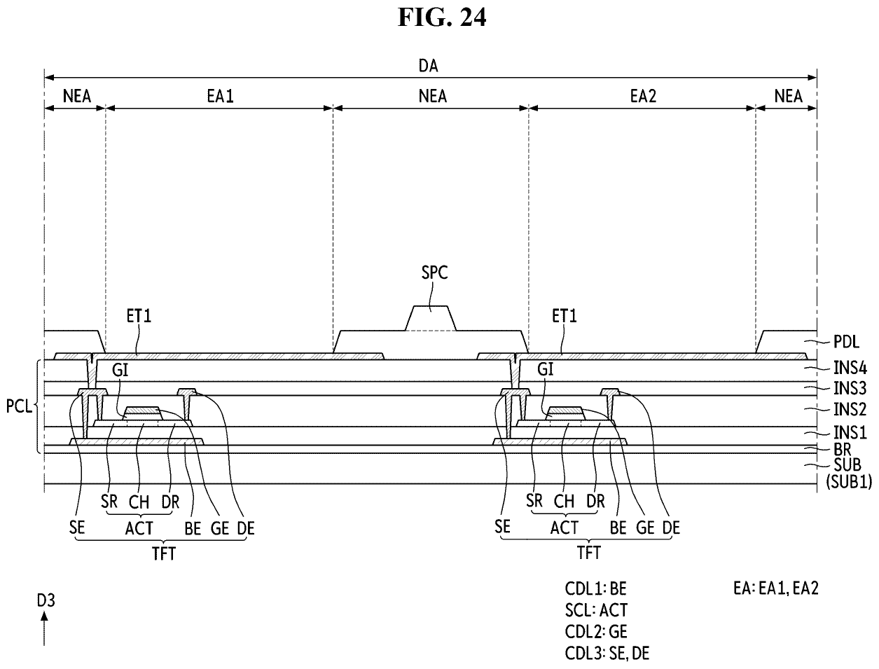

Referring to FIG. 24, a pixel defining layer PDL and a spacer SPC may be formed in the non-light emitting area NEA on the substrate SUB on which the first electrodes ET1, etc. are disposed. As an example, the pixel defining layer PDL and the spacer SPC may be formed in the non-light emitting area NEA by a process of forming an insulating film using at least one insulating material (for example, an organic insulating material such as polyimide (PI)) and an etching process of the insulating film. In an embodiment, the pixel defining layer PDL and the spacer SPC may be formed simultaneously by forming or etching the insulating film to a different thickness for each portion using a halftone mask. By way of example, the pixel defining layer PDL and the spacer SPC may be sequentially formed using different masks. In an embodiment, the pixel defining layer PDL may be formed to cover edges of the first electrodes ET1 and expose the remaining area of the first electrodes ET1.

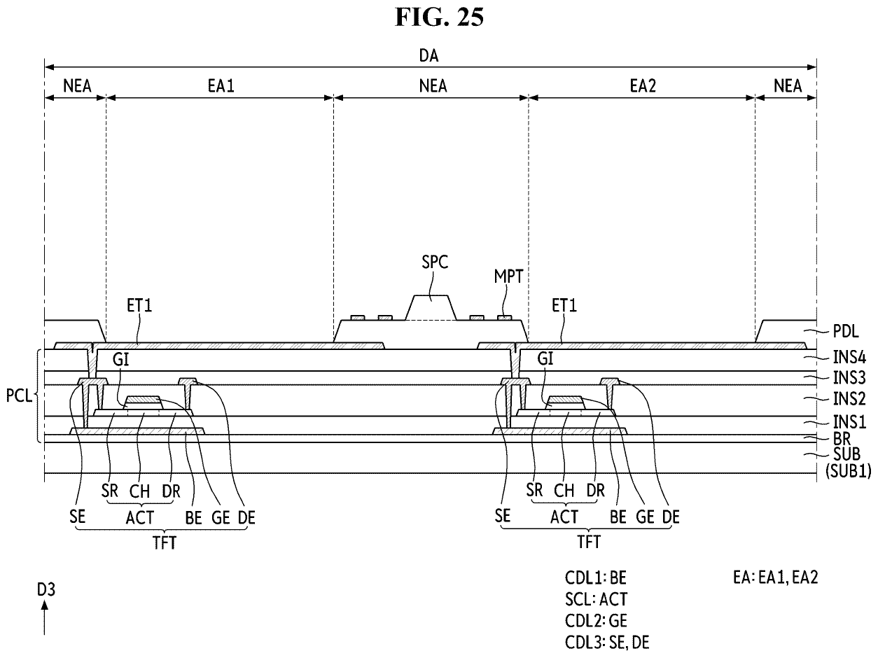

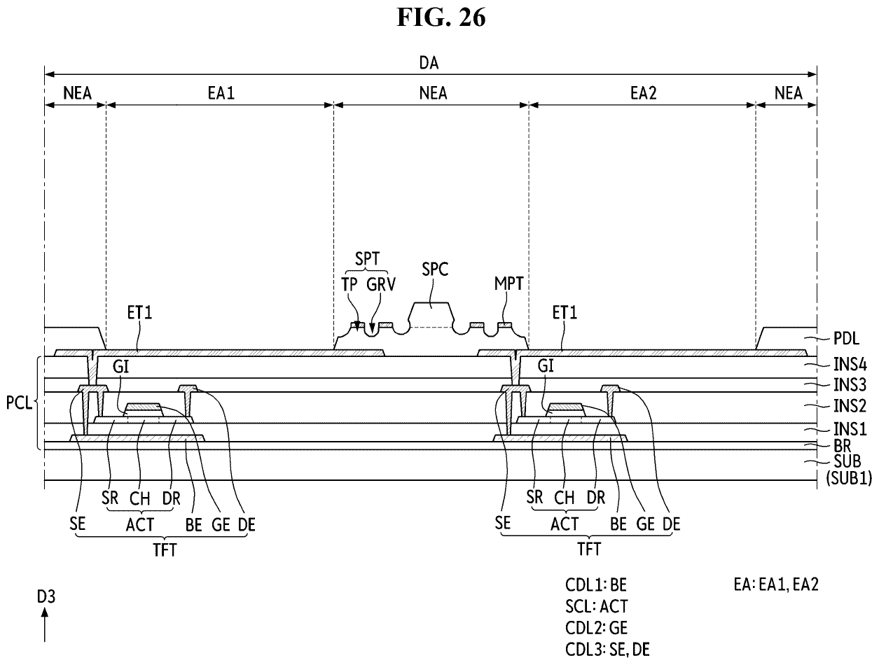

Referring to FIGS. 25 and 26, a second pattern MPT may be formed on a portion of at least one of the pixel defining layer PDL and the spacer SPC, and a first pattern SPT may be formed in (or formed on) at least one of the pixel defining layer PDL and the spacer SPC by using the second pattern MPT as a mask. As described above, the position, shape, size, and/or number of the first pattern SPT and the second pattern MPT may vary depending on the embodiments.

In an embodiment, as illustrated in FIG. 25, at least one second pattern MPT may be formed around the spacer SPC. As an example, a single second pattern MPT or second patterns MPT may be formed on a portion of at least one of the pixel defining layer PDL and the spacer SPC. In an embodiment, the second pattern MPT may be formed around the spacer SPC by a process (for example, a deposition process) for forming a metal film or oxide film using a metal or oxide (for example, a metal oxide or non-metal oxide including ZIO, IGZO, or TIZO) and a patterning process (for example, a photoresist process and a wet etching process, etc.) of the metal film or oxide film. FIG. 25 illustrates an embodiment in which the second patterns MPT are formed on the pixel defining layer PDL at portions positioned at sides of the spacer SPC as in the embodiment of FIG. 14, but at least one of the position, shape, size, and number of the second patterns MPT may vary depending on the embodiments. As an example, the position, shape, size, and/or number of the second patterns MPT may vary depending on one of the embodiments described above or a combination of at least two embodiments thereof.

Referring to FIG. 26, the first pattern SPT may be formed using the second pattern MPT. For example, a groove GRV may be formed by partially removing at least one of the pixel defining layer PDL and the spacer SPC around the second pattern MPT using the second pattern MPT as a mask (for example, a hard mask). As an example, the groove GRV may be formed around the second pattern MPT through a dry ashing process using the second pattern MPT as a hard mask. Accordingly, a first pattern SPT including a protrusion TP below the second pattern MPT and a groove GRV around the protrusion TP may be formed.

In an embodiment, after forming the first pattern SPT, a process of removing the second pattern MPT may be selectively performed. As an example, in case that it is desired to manufacture the display panel 110 that does not include the second pattern MPT as in the embodiment of FIG. 18, the process of removing the second pattern MPT may be performed after forming the first pattern SPT. On the other hand, in case that it is desired to manufacture the display panel 110 including the second pattern MPT, the process for removing the second pattern MPT may not be performed.

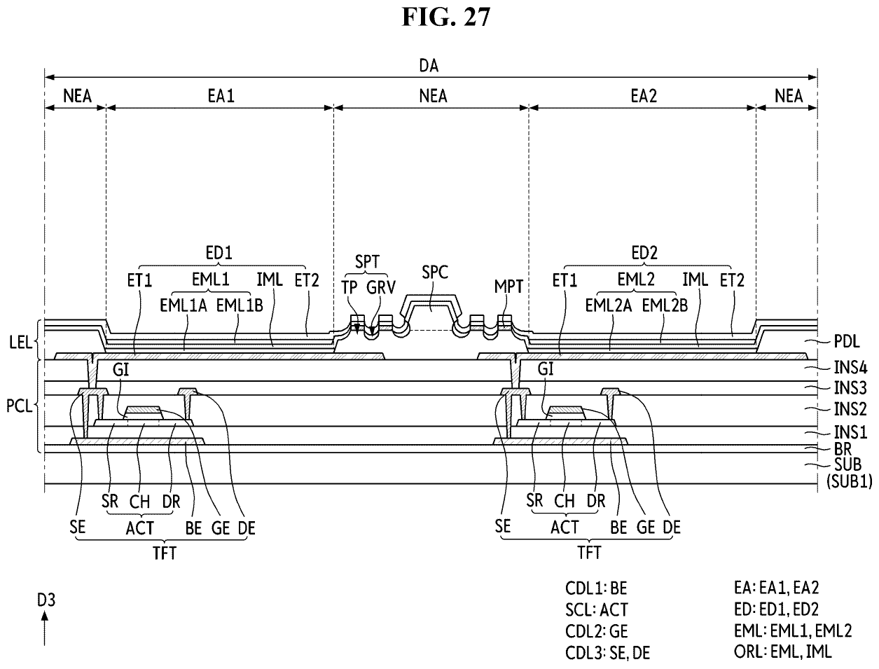

Referring to FIG. 27, each light emitting element ED may be formed by sequentially forming at least one light emitting layer EML and a second electrode ET2 in the light emitting areas EA. For example, an organic layer ORL including each of the light emitting layers EML may be formed on the first electrodes ET1, and the second electrode ET2 may be formed on the organic layer ORL.

In an embodiment, the organic layer ORL may further include an intermediate layer IML that overlaps the light emitting layers EML. For example, the step of forming the organic layer ORL may include forming a light emitting layer EML of each of the light emitting elements ED and forming an intermediate layer IML of the light emitting elements ED. As an example, in case that light emitting elements ED with a two-tandem structure as shown in FIG. 14 are formed, a first light emitting layer EML1, an intermediate layer IML, a second light emitting layer EML2, and a second electrode ET2 may be sequentially formed on each first electrode ET1.

In an embodiment, the light emitting layer EML may be individually formed in each light emitting area EA. As an example, each light emitting layer EML may be formed in each light emitting area EA using a fine metal mask or the like within the spirit and the scope of the disclosure.

In an embodiment, the intermediate layer IML and the second electrode ET2 may be entirely formed in the display area DA in the form of a common film. For example, each of the intermediate layer IML and the second electrode ET2 may be entirely formed (for example, entirely deposited) in the display area DA including light emitting areas EA and a non-light emitting area NEA surrounding the light emitting areas EA. In case that at least one of the first pattern SPT and the second pattern MPT is formed in the non-light emitting area NEA, the intermediate layer IML and the second electrode ET2 may have a level difference corresponding to the level difference caused by the first pattern SPT and/or the second pattern MPT, or may be partially disconnected or isolated around the first pattern SPT and/or the second pattern MPT. For example, each of the intermediate layer IML and the second electrode ET2 may be partially disconnected or have a level difference on the first pattern SPT.

Thereafter, the light emitting element layer LEL may be encapsulated using the protective layer PRL (for example, the upper substrate SUB2) or the encapsulation layer ENL described above. For example, the filler FIL and the protective layer PRL may be sequentially formed or disposed on the light emitting element layer LEL, or the encapsulation layer ENL may be formed thereon. As a result, the display area DA including the light emitting elements ED may be appropriately encapsulated.

According to the display device 100 and the method of manufacturing the same according to the above-described embodiments, a pattern that blocks or delays a path of moisture permeation or leakage current may be disposed around of the light emitting area EA (for example, on a portion of the pixel defining layer PDL disposed in the non-light emitting area NEA or around the spacer SPC, etc.). For example, the first pattern SPT including the protrusion TP and the groove GRV may be disposed or formed in a portion of the pixel defining layer PDL disposed between the light emitting areas EA, or in a spacer SPC on the pixel defining layer PDL or around the spacer SPC. The first pattern SPT may be formed in (or formed on) at least one of the pixel defining layer PDL and the spacer SPC. In an embodiment, the second pattern MPT that is used as a mask for forming the first pattern SPT may be disposed on the protrusion TP of the first pattern SPT.

Accordingly, the path of moisture permeation or leakage current may be blocked or delayed around the first pattern SPT and/or the second pattern MPT. For example, the first pattern SPT and/or the second pattern MPT may cause partial disconnection or a level difference in at least one common film disposed on the first pattern SPT and/or the second pattern MPT. As an example, the intermediate layer IML and/or the second electrode ET2 of the light emitting elements ED may be disposed on the pixel defining layer PDL and the spacer SPC in the non-light emitting area NEA and may be partially disconnected (or isolated) or have the level difference by the first pattern SPT and/or the second pattern MPT. Accordingly, it is possible to block or reduce contaminants or moisture from permeating into damaged portions of the pixel defining layer PDL and/or the spacer SPC via the intermediate layer IML and/or the second electrode ET2 of the light emitting elements ED, or leakage current from flowing through the intermediate layer IML of the light emitting elements ED. For example, in case that the intermediate layer IML of the light emitting elements ED is partially disconnected around the light emitting areas EA, it is possible to effectively prevent or reduce the permeation of moisture or contaminants or the flow of leakage current through the intermediate layer IML.

According to the above-described embodiments, damage or performance degradation of the light emitting element ED due to moisture permeation or leakage current may be prevented, and defects or luminance decreases in the pixel PX may be prevented or reduced. Accordingly, reliability of the pixel PX and the display device including the same may be improved.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A display device comprising:
a substrate including a display area including light emitting areas;
pixels disposed on the substrate and including light emitting elements disposed in the light emitting areas;
a pixel defining layer disposed on the substrate and surrounding the light emitting areas;
a spacer disposed on a portion of the pixel defining layer; and
a first pattern formed in at least one of the pixel defining layer and the spacer, the first pattern including a protrusion and grooves disposed at sides of the protrusion.

2. The display device of claim 1, wherein the grooves are entirely disposed around a circumference of the protrusion.

3. The display device of claim 1, further comprising a second pattern disposed on the protrusion.

4. The display device of claim 3, wherein the second pattern includes a metal or an oxide.

5. The display device of claim 3, wherein the second pattern completely covers an upper surface of the protrusion.

6. The display device of claim 3, wherein the protrusion has a shape and size substantially corresponding to a shape and size of the second pattern.

7. The display device of claim 1, wherein the spacer is disposed between a first light emitting area and a second light emitting area that are adjacent to each other in a first direction among the light emitting areas, and extends in a second direction intersecting the first direction.

8. The display device of claim 7, wherein the first pattern is formed in the pixel defining layer and disposed at sides of the spacer in the first direction.

9. The display device of claim 7, wherein the first pattern is disposed between the first light emitting area and the second light emitting area and surrounds the spacer.

10. The display device of claim 1, wherein each of the light emitting elements includes:
a first electrode disposed on the substrate and disposed in a light emitting area of each of the pixels;
a light emitting layer disposed on the first electrode; and
a second electrode disposed on the light emitting layer and entirely disposed in the display area.

11. The display device of claim 10, wherein the second electrode is partially disconnected or has a level difference on the first pattern.

12. The display device of claim 10, wherein each of the light emitting elements further includes an intermediate layer disposed between the first electrode and the second electrode and overlapping the light emitting layer.

13. The display device of claim 12, wherein
the intermediate layer is entirely disposed in the display area, and
the intermediate layer is partially disconnected or has a level difference on the first pattern.

14. The display device of claim 12, wherein a height difference between the protrusion and the grooves is substantially greater than or equal to a thickness of the intermediate layer.

15. The display device of claim 1, further comprising a filler and an upper substrate disposed on the light emitting elements.

16. The display device of claim 1, further comprising a multi-layer encapsulation layer disposed on the light emitting elements.

17. A method of manufacturing a display device, the method comprising:
preparing a substrate including light emitting areas and a non-light emitting area disposed between the light emitting areas;
forming first electrodes in the light emitting areas on the substrate;
forming a pixel defining layer and a spacer in the non-light emitting area on the substrate;
forming a first pattern including a groove in at least one of the pixel defining layer and the spacer; and
forming an organic layer including respective light emitting layers on the first electrodes and forming a second electrode on the organic layer, wherein
the second electrode is entirely formed in a display area including the light emitting areas and the non-light emitting area, and
the second electrode is partially disconnected or has a level difference on the first pattern.

18. The method of claim 17, wherein the forming of the first pattern includes:
forming a second pattern on a portion of at least one of the pixel defining layer and the spacer; and
forming the groove in at least one of the pixel defining layer and the spacer by using the second pattern as a mask.

19. The method of claim 18, wherein the second pattern is formed of a metal or an oxide.

20. The method of claim 17, wherein
the organic layer further includes an intermediate layer overlapping the light emitting layers, and
the intermediate layer is entirely disposed in the display area and is partially disconnected or has a level difference on the first pattern.

21. An electronic device for providing an image, comprising:
a display device comprising:
a substrate including a display area including light emitting areas;
pixels disposed on the substrate and including light emitting elements disposed in the light emitting areas;
a pixel defining layer disposed on the substrate and surrounding the light emitting areas;
a spacer disposed on a portion of the pixel defining layer; and
a first pattern formed in at least one of the pixel defining layer and the spacer, the first pattern including a protrusion and grooves disposed at sides of the protrusion.

22. The electronic device of claim 21, wherein the grooves are entirely disposed around a circumference of the protrusion.

23. The electronic device of claim 21, wherein the spacer is disposed between a first light emitting area and a second light emitting area that are adjacent to each other in a first direction among the light emitting areas, and extends in a second direction intersecting the first direction.
